(19) United States
(12) Patent Application Publication
(10) Pub. No.: US 2018/0300435 A1
(43) Pub. Date: Oct. 18, 2018

(54) AUTOMATED WAREHOUSE DESIGN AND SIMULATIONS

(71) Applicant: Lineage Logistics, LLC, Irvine, CA (US)

(72) Inventors: Christopher Eckman, San Francisco, CA (US); Elliott Gerard Wolf, San Francisco, CA (US); Sudarsan Thattai, Irvine, CA (US); Shawn Merrill, Irvine, CA (US); Jammie Morris, Irvine, CA (US)

(21) Appl. No.: 15/947,130

(22) Filed: Apr. 6, 2018

Related U.S. Application Data
(60) Provisional application No. 62/482,613, filed on Apr. 6, 2017.

(51) Int. Cl. G06F 17/50; G06Q 10/08; G06Q 10/06

(52) U.S. Cl. CPC G06F 17/5004; G06Q 10/06395; G06Q 10/087

(57) ABSTRACT

This document generally describes simulating warehouse automation designs and evaluating the results of such simulations to optimize automated warehouse designs. Warehouse automation can be simulated, for example, to determine an optimal warehouse automation design given a variety of parameters that are specific to the warehouse, such as the expected customer inventory demands over time, the layout of the warehouse, and/or the specific automation features (e.g., machines) that are possible within the warehouse. Such warehouse simulations can be repeatedly run and warehouse automation designs can be modified to identify an optimal warehouse automation design that will, for example, maximize the efficiency of the warehouse by minimizing pallet place and pull times, minimizing truck load/unload times, and minimizing/eliminating failures during which the warehouse is not able to meet threshold performance metrics.

### CROSS-REFERENCE TO RELATED APPLICATIONS

This application claims the benefit of priority under 35 U.S.C. § 119(e) of U.S. Application Ser. No. 62/482,613, filed Apr. 6, 2017, which is hereby incorporated by reference in its entirety.

### TECHNICAL FIELD

This document generally describes technology for optimizing the design and use of automated warehouses for storing pallets and other physical goods.

### BACKGROUND

Warehouses include warehouse racks to store pallets of goods. Pallets are generally flat transport structures that support goods in a stable manner and that also include structures that are adapted to fit forklifts and/or other devices/machines to move pallets. Stacked on top of pallets are packages of various products. The weight and volume stacked on a pallet varies, resulting in a mix of heights for a given inventory profile. Warehouses have been designed to permit forklifts to put and pull pallets from racks as needed.

Automated warehouses have also been designed. Automated warehouses include a variety of features to permit machines to automatically (without human direction) put and pull pallets from racks. Automated warehouses can include a variety of features, such as conveyor belts to transport pallets from a warehouse dock (where pallets are loaded and unloaded from trucks) to cranes that are designed to lift pallets to different rows on a warehouse rack. The racks can be equipped with carts on each row of the rack that are designed to carry pallets from the crane to a final storage location in the rack for the pallet.

### SUMMARY

This document generally describes computer-based technology for simulating warehouse automation designs and evaluating the results of such simulations to inform a variety of decisions. For example, warehouse automation can be simulated for the purpose of determining an optimal warehouse automation design given a variety of parameters that are specific to the warehouse, such as the expected customer inventory demands over time, the layout of the warehouse, and/or the specific automation features (e.g., machines) that are possible within the warehouse. Such warehouse simulations can be repeatedly run on different warehouse automation designs to identify an optimal warehouse automation design that will, for example, maximize the efficiency of the warehouse by minimizing pallet place and pull times, minimizing truck load/unload times, and minimizing/eliminating failures during which the warehouse is not able to meet threshold performance metrics.

In another example, warehouse automation can be simulated for the purpose of determining whether an existing automated warehouse can accommodate a new or modified customer storage profile in addition to the existing inventory that the warehouse handles. Such warehouse simulations can run to determine the impact of such a new or modified customer storage profile on the performance of the automated warehouse (e.g., performance decrease or increase, change in performance) and/or whether accommodating the new or modified customer storage profile will cause the automated warehouse to fail (e.g., warehouse is not able to meet threshold performance metrics). Such warehouse simulations can be repeatedly run with changes to the new/modified customer profile at each iteration to determine whether and what type of adjustment to the new/modified customer storage profile would provide optimal performance for the automated warehouse.

Other uses and features of automated warehouse simulations are also possible.

In some implementations, a system for optimizing warehouse automation design include an automated warehouse design database that is programmed to store a warehouse automation model for a current automation design for a warehouse, the current automation design including automation components to automate storage of pallets within the warehouse. Such a system can also include a historical inventory database that is programmed to store historical inventory data for the warehouse, the historical inventory data identifying, at least, pallets stored in the warehouse, times at which the pallets were stored and removed from the warehouse, and truck identifiers for trucks carrying the pallets. Such a system can additionally include a computer system (e.g., an automated warehouse design simulator implemented one or more more computers in one or more locations) including one or more processors that are programmed to: access the historical inventory information and the warehouse automation model; chronologically simulate, according to the specific timing included in the historical inventory data, storage and retrieval of the pallets on the current automation design for the warehouse using the warehouse automation model, wherein the warehouse automation model (i) maps functional and physical relationships between the automation components, and (ii) includes movement parameters for the automation components; detect arrival of the pallets at checkpoints within the current automation design for a warehouse; record timestamps for simulated times at which the pallets arrived at the checkpoints; assess performance of the current automation design for a warehouse under the simulation based on analysis of the recorded timestamps; and output the performance information for the current automation design for a warehouse.

Such implementations can optionally include one or more of the following features. The automation components can include conveyor belts to transport pallets from a dock to racks in the warehouse, cranes to carry pallets to different rack levels, and carts to transport pallets across rack openings on a same rack level. For each of the automation components, the movement parameters can include a rate of acceleration, a maximum velocity, a receiving delay, a process delay, and an eject delay. The checkpoints can include doors entering the warehouse, transition points between the dock and the conveyor belts, transition points between the conveyor belts and the cranes, transition points between the cranes and the carts, and placement of pallets in target rack openings in the warehouse. The performance assessment can include determining whether the current automation design for a warehouse failed to meet one or more performance metrics under the simulation. The performance metrics can include a maximum amount of time to transport pallets between trucks and storage locations. The performance metrics can include a maximum amount of time for trucks to wait to dock at the warehouse. The performance metrics can include a maximum amount of time for trucks to be loaded or unloaded with pallets. In response to determining that the current automation design failed, performing additional operations can include modifying one or more of the automation components in the current automation design to generate a revised automation design for the warehouse; generating a revised warehouse automation model for the revised automation design; repeating the chronological simulation, detecting, recording, and assessing with the revised warehouse automation model and the same historical inventory data; determining whether the revised automation design for the warehouse is an improvement over the previous automation design for the warehouse based on comparison of the performance assessments; and outputting information identifying an optimal automation design for the warehouse based on the determination. Such a system can further include a warehouse management system that is programmed to perform the following operations to direct the automation components on the placement of a pallets in the storage racks.

The details of one or more embodiments are set forth in the accompanying drawings and the description below. Other features and advantages will be apparent from the description and drawings, and from the claims.

### DESCRIPTION OF DRAWINGS

FIG. 1 depicts an example system for optimizing an example warehouse rack.

FIGS. 2A-D provide different views of an example automated warehouse and its components.

FIGS. 3A-B are graphs that depict example scenarios in which inventory for a storage facility vary over time.

FIG. 4 is a flowchart of an example technique for performing automated warehouse simulations to determine an optimal warehouse automation design.

FIG. 5 is an example warehouse automation simulation system that can be used to simulate warehouse designs.

FIG. 6 is a flowchart of an example technique for generating a warehouse automation model.

FIGS. 7A-C depict example data transformations that are performed as part of an example technique to generate a warehouse automation model.

FIG. 8 is a conceptual diagram depicting automated warehousing actions that are simulated and data that is recorded as part of the simulation.

FIG. 9 is a flowchart of an example technique for simulating use of a warehouse automation design.

FIGS. 10A-C depict example techniques for simulating inbound pallet movements to storage locations within the warehouse.

FIGS. 11A-C depict example techniques for simulating outbound pallet movements to storage locations within the warehouse.

FIGS. 12A-C depict the example simulation of pallets with different SKUs being stored in and removed from racks in a warehouse over time.

FIGS. 13A-H are 3D renderings of automated warehouse simulations.

FIGS. 14A-B are a flowchart of an example technique for recording simulation data and an example log of simulation data for an automated warehouse simulation.

FIG. 15 is a flowchart of an example technique for analyzing the simulation data and determining simulation results.

FIGS. 16A-D are charts depicting example automated warehouse simulation results.

FIG. 17 is a flowchart of an example technique for simulating the impact of an inventory modification for an automated warehouse on the warehouse's performance.

FIG. 18 is a block diagram of example computing devices that may be used to implement the systems and methods described in this document.

Like reference symbols in the various drawings indicate like elements.

### DETAILED DESCRIPTION

This document generally describes systems, methods, devices, and techniques for simulating the use of warehouse automation designs and evaluating the results of such simulations. Warehouse automation designs can be specifically evaluated based on real-world conditions for a warehouse, such as being based on historical/expected inbound and outbound inventory demands for customers who are/will be using the warehouse, actual timing for automation features within the warehouse, and/or other factors. Simulations can be used to make a variety of determinations, such as whether a current automated warehouse design will be suitable for expected inventory demands for the warehouse and/or whether a modification to the inventory demands can be accommodated by the automated warehouse with less than a threshold degradation in performance. Simulations can be repeatedly performed while varying parts of the simulation, such as varying features that are part of the warehouse automation design, varying the dimensions and/or layout of the warehouse itself (presuming that the warehouse has not yet been constructed), and/or varying the inventory demands on the warehouse. Such variations can be used to determine an optimal solution for the automated warehouse, such as an optimal automation design for the warehouse, an optimal size/layout for the warehouse, and/or an optimal inventory profile for the warehouse. Other uses of the simulations are also possible.

This document includes general discussions of this technology as well as an experimental implementation that illustrates the technology and various design considerations.

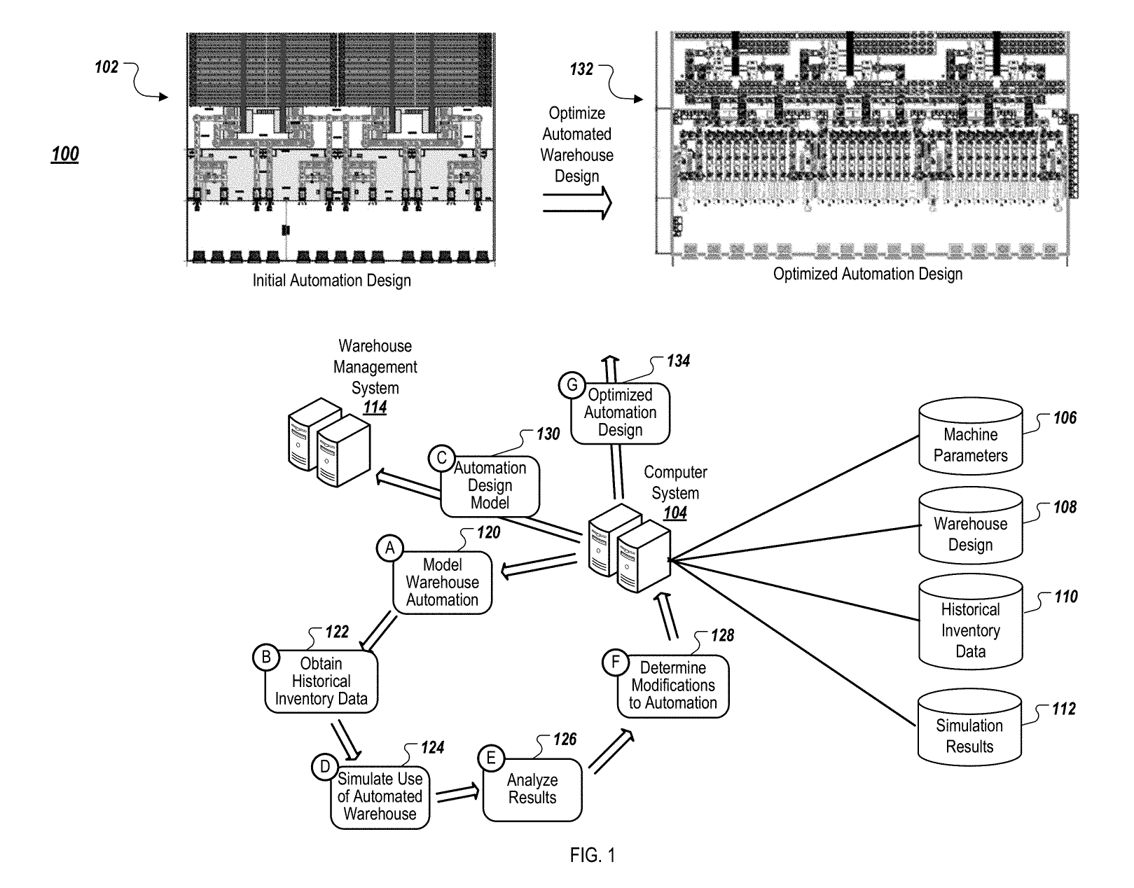

FIG. 1 depicts an example system 100 for optimizing an example warehouse automation design 102. The example system 100 includes a computer system 104 (e.g., server system, cloud-based computer system, desktop, laptop, mobile computing device, other computing device/system) that is programmed to determine an optimized design for the automated warehouse 102 based, at least in part, on historical inventory data 110 modeling the use of the facility (e.g., modeling the size and frequency of inventory stored at the facility over time), machine parameters 106 modeling the performance of automated features (e.g., acceleration, speed, delay, capacity), and warehouse designs 108 modeling the warehouse (e.g., warehouse dimensions) and proposed automation designs (e.g., number and types of conveyors, cranes, carts, and the layout there between) for the facility.

For example, the historical inventory data 110 can identify the timing and volume of inbound and outbound pallets for the facility, along with distributions of different sized pallets over time. The facility can have one or more storage profiles, such as having multiple storage profiles that correspond to different companies/clients that use the facility and/or different products that are stored at the facility.

The system 100 also includes a Warehouse Management System 114 (also referred to as “WMS”) that is a specialized computer system to manage storage and retrieval of inventory at the facility, and to interface with devices and components within the facility, such as automated components within the automated warehouse. For example, the WMS 110 can determine where pallets arriving at the facility should be placed (e.g., identifying particular storage locations in the rack for pallets), manage and track the locations of pallets, identify pallets that should be removed for shipment out of the facility, determine optimal paths along which the pallets should travel through the automated warehouse, and control automated features to ensure that pallets are picked and placed at the correct locations.

The computer system 104 can determine an optimal design for the automated warehouse 102 that is specifically tailored to the storage profile(s) represented in the historical inventory data 110 for the facility, the physical parameters of the facility (as indicated by the warehouse deign 108), and the specific automated component parameters 106 for the components within the warehouse. An optimal design is one in which the automated warehouse is able to accommodate all pallets at a given point in time (leaving minimal or no orphaned pallets that are unable to be stored because the racks are filled) while minimizing the time to perform pick and place operations, as well as minimizing unused rack space (space between the top of a pallet and the bottom of the next rack shelf above the pallet). For example, the initial automation design 102 (presented as a top down view of the warehouse and the automation components) that is depicted includes a pairs of two conveyors across a couple different modules. In contrast, the example optimized automation design 132 is depicted in which multiple redundant conveyors, which can be determined to be the optimal configuration for the specific storage facility, its physical parameters, and its specific usage. The computer system 104 can determine customized optimizations storage facilities and may adjust them over time as the use of facilities changes over time (e.g., different products are stored at the facilities, different companies/client are using the storage facility).

The system 100 can optimize the automated warehouse design 102 (to be have an optimized design 132) over a variety of different steps to identify optimized automation features and to efficiently use the optimized features. For example, rack optimization techniques performed by the system 100 and its components (e.g., computer system 104, WMS 110) can include:

(A, 120) generating an automated warehouse model that models the initial automated warehouse design 102 and how the automation components within the design 102 functionally and physically related to each other, which can be generated based on the warehouse design 108 and the machine parameters 106;

(B, 122) obtaining historical inventory data (e.g., time sequence of inbound and outbound inventory previously experienced by the warehouse) for companies/clients currently and/or projected to use the warehouse;

(C, 124) providing the automated design model to the WMS 114 for the WMS 114 to use when simulating use of the automated warehouse design, which can be used to determine the performance of the automated warehouse for the historic/expected inventory for the warehouse;

(D, 126) simulating the use of the automated warehouse for storing and retrieving the historic/expected inventory for the warehouse using the warehouse automation model;

(E, 128) the results of the simulation can be analyzed to determine how well the automated design performed in putting and pulling historic/expected inventory demands for the warehouse;

(F, 130) determining modification to the automation features that are included in the automation design (e.g., increasing/reducing number of conveyors, reducing/increasing size of dock, reducing/increasing number of doors, changing orientation/alignment of components) and repeating the simulation exercise (A-D), as necessary; and

(G, 134) outputting an optimized automation design when, after iterative analysis of different automation designs has been performed and compared, an optimal automation design has been identified for the specific warehouse, the specific automation components available for inclusion in the warehouse, the specific combination of historic/expected inventory for the warehouse, and/or the layout/dimensions of the facility.

Automated Warehouse Components

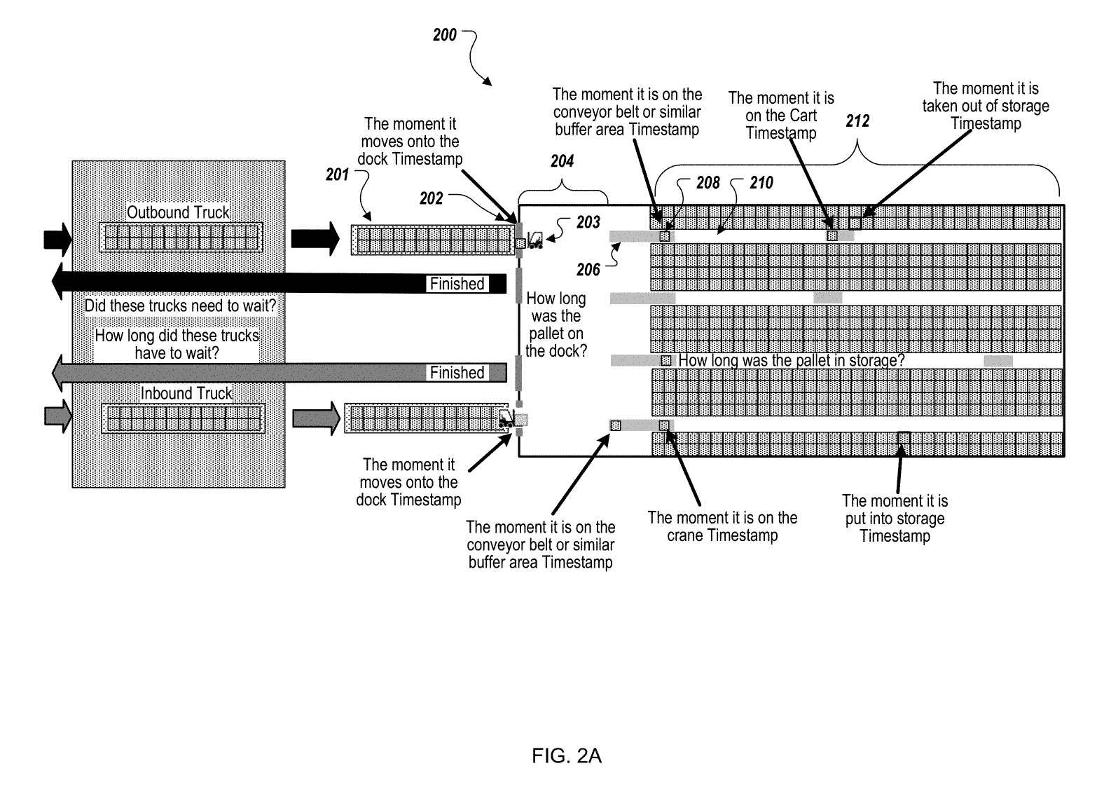

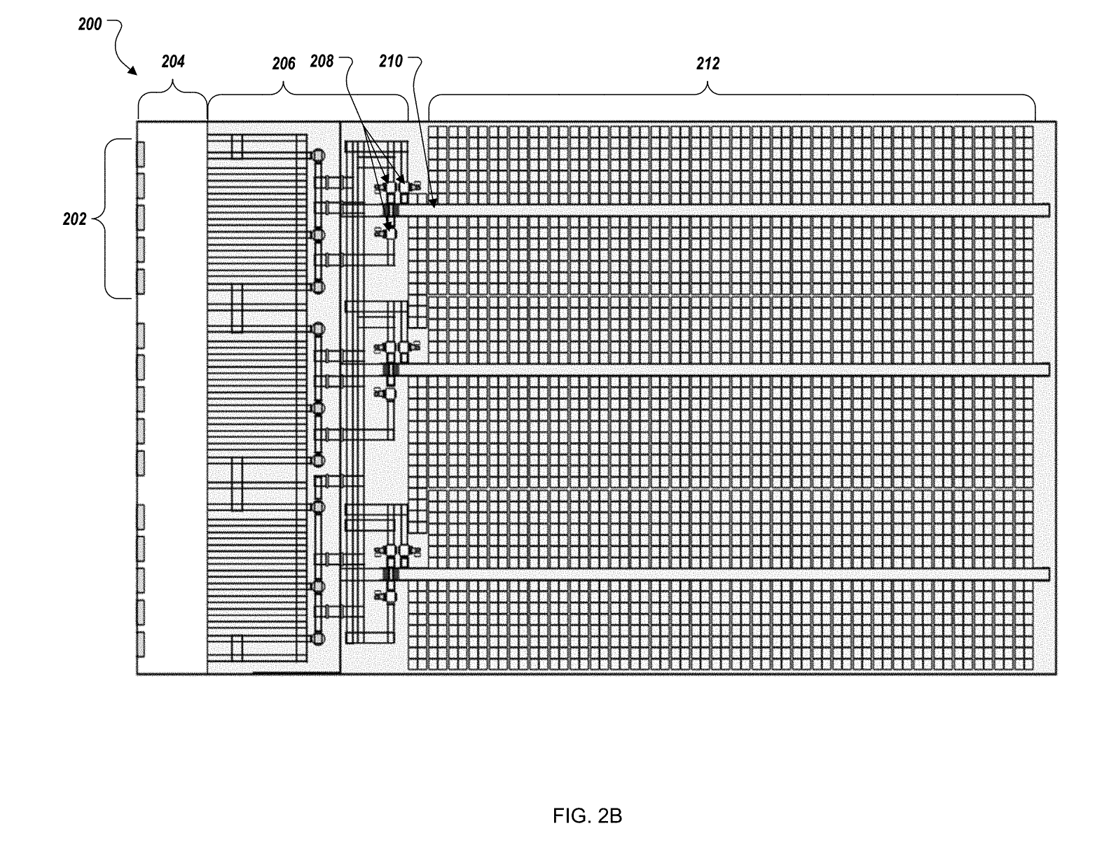

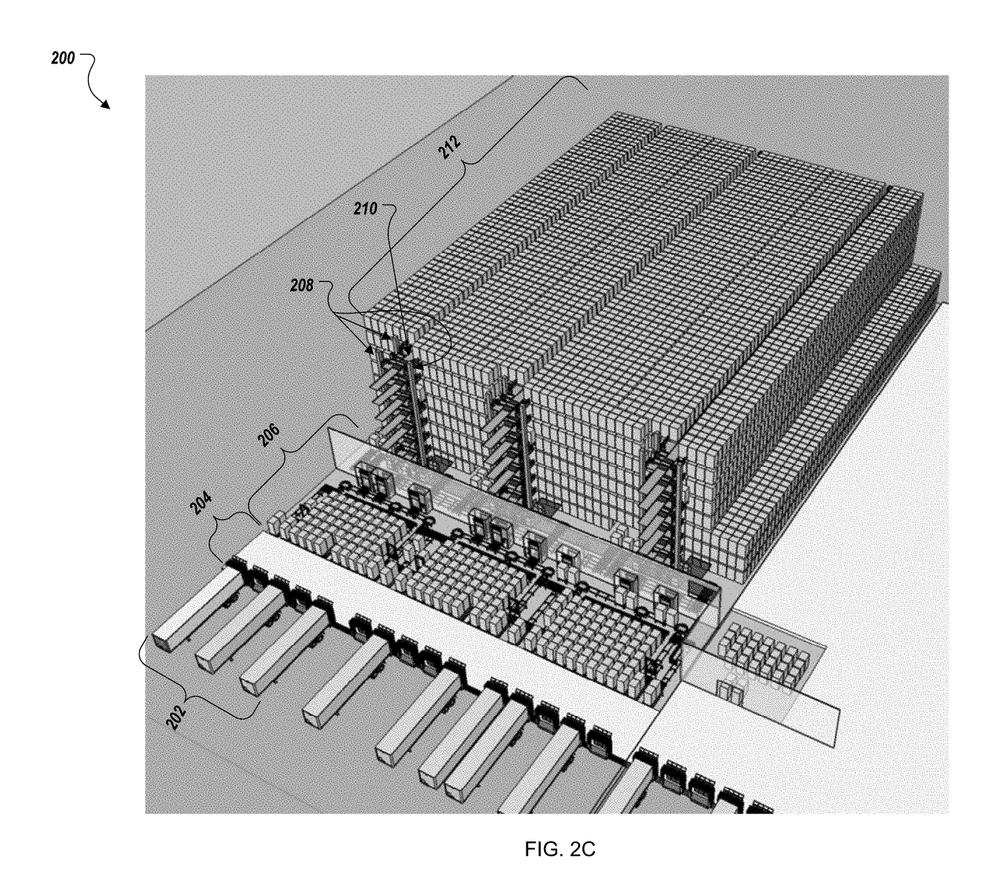

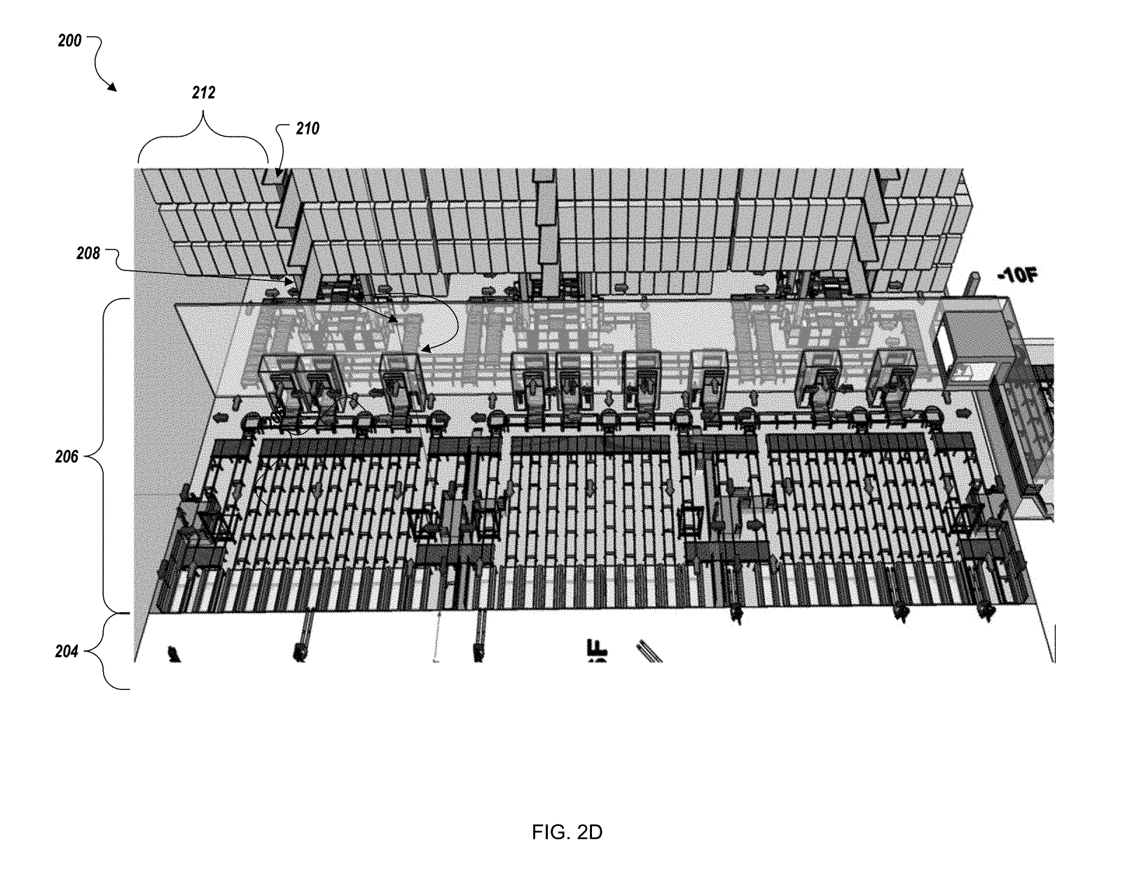

FIGS. 2A-D provide different views of an example automated warehouse 200 and its components 201-212, which can be arranged in different configurations to generate an automated warehouse design. The example components 201-212 include truck doors/bays 202 that serve as an interface between trucks 201 and the warehouse 200, and through which pallets from the trucks 201 are loaded/unloaded. The components 201-212 further include forklifts 203 that serve as the primary mechanism through which pallets are loaded/unloaded from the trucks 201 (other mechanisms for loading/unloading the pallets can also be used). The forklifts 203 can be manually operated and/or automatic (machine) operated. Forklifts 203 can travel across the dock 204, which is an open part of the warehouse 200 that permits maneuvering between the doors/bays 202 and the automated components of the warehouse 200, which include conveyors 206, cranes 208, and carts 210 in the storage racks 212. The conveyors 206 can carry pallets from the forklifts 203 to the cranes 208, which lift the pallets to the appropriate row/level on the racks 212. The carts 210 can deliver the pallets from the cranes 208 to the assigned storage location for the pallets. Additional and/or alternative automation features are also possible.

Control algorithms, such as those running on the WMS 114, can be used to direct and control the operation of the warehouse 200 and its components 201-212 to ensure that pallets are carried to the appropriate locations in an efficient manner.

Referring to FIG. 2A, an example top down view of the warehouse 200 is presented with annotations identifying different performance factors for an automated warehouse as they relate to the warehouse components 201-212. Information for determining these performance factors can be recorded during simulations, such as recording timestamps when trucks and/or pallets arrive at various checkpoints within the warehouse 200, such as locations where pallets change direction through automation components within the warehouse design being simulated (e.g., intersections between different conveyors, intersections between conveyors and cranes, intersections between cranes and shuttle systems). For example, anytime a pallet makes a turn (e.g., changes direction) or otherwise has its path modified (e.g., change speed, stop) within the warehouse simulation, a coordinate where the event (e.g., turn, other path modification) occurred within the warehouse simulation (using a grid-based coordinate system to represent the location of objects/components warehouse), an identifier for the object (e.g., pallet), and a timestamp at which the event occurred can be recorded.

Regarding truck performance, the amount of time that trucks 201 have to wait to be docked at the doors/bays 202 is a first performance factor that can be analyzed. For example, if all of the doors/bays 202 are occupied when a truck 201 arrives at the warehouse 200, that truck will have to wait until one of the doors/bays 202 opens up. This waiting is an inefficiency that the simulation can identify. The waiting can be indicated, for example, by a first record indicating a time when the truck 201 was at the warehouse 200 and ready to be docked (a first example checkpoint) and a second record indicating a later time when the truck 201 was able to be docked (a second example checkpoint). The difference between these two times is the wait time for the truck 201.

The truck 201 docking at the door/bay 202 can be a checkpoint that is recorded and, in addition to being used to determine wait times, can be used to determine an amount of time it takes for the truck 201 to be unloaded and/or loaded with pallets. The truck 201 leaving the door/bay 202 can be another checkpoint that is recorded to bookend these time intervals.

Regarding individual pallet performance in the automated warehouse 200, the forklift 203 unloading a pallet from the truck 201 can be a checkpoint that is recorded to start a time period for (a) the time duration for the pallet to travel across the dock 204 to the conveyors 206 and (b) the overall time duration for the pallet to travel from the truck 201 to its ultimate storage location in the racks 212. Once the forklift 203 delivering the pallet to a conveyor 206 can be another checkpoint that is recorded, which can be used to determine (a) the ending time for the pallet to travel across the dock 204 to the conveyors 206 and (b) the time for the pallet to travel along the conveyors 206. Other checkpoints that prompt records being created for the pallet can include the pallet arriving at the crane 208, the pallet arriving at the cart 210, and the pallet arriving at its storage location in the rack 212. These records corresponding to the pallet arriving at various locations along its path from the truck 201 to a storage location in the racks 212 can be used to determine one or more time intervals for the pallet's movement through the warehouse 200, which can indicate performance of the warehouse 200. For example, the longer it takes for a pallet to arrive at its storage location, the more inefficient the automated warehouse design is at handling the historic/expected inventory for the warehouse 200.

Similar records can be generated as pallets are retrieved from the storage locations in the racks 212. For example, records can be generated when a request for the pallet is generated by the system, when the cart 210 retrieves the pallet from its storage location, when the pallet arrives at the crane 208, when the pallet arrives at the conveyors 206, when the forklift 203 retrieves the pallet from the conveyor 206, and when the forklift 203 loads the pallet onto the truck 201. Additional and/or alternative checkpoints and records can be generated.

Referring to FIG. 2B, a more detailed top down view of an example warehouse 200 is depicted. Referring to FIG. 2C, a 3D perspective view of a rendering of the warehouse 200 is depicted. Referring to FIG. 2D, a straight-on 3D view of the warehouse 200 from a vantage point above the docks/bays is depicted.

Example Inventory Variability Over Time

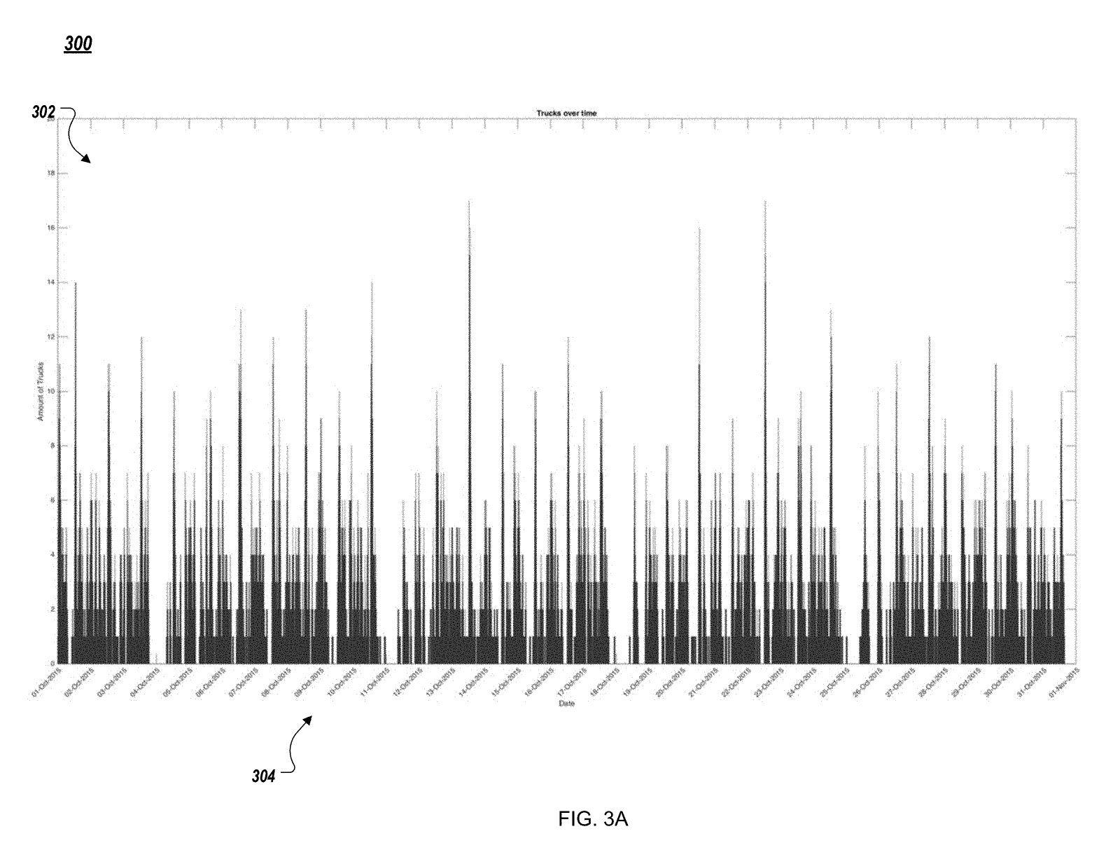

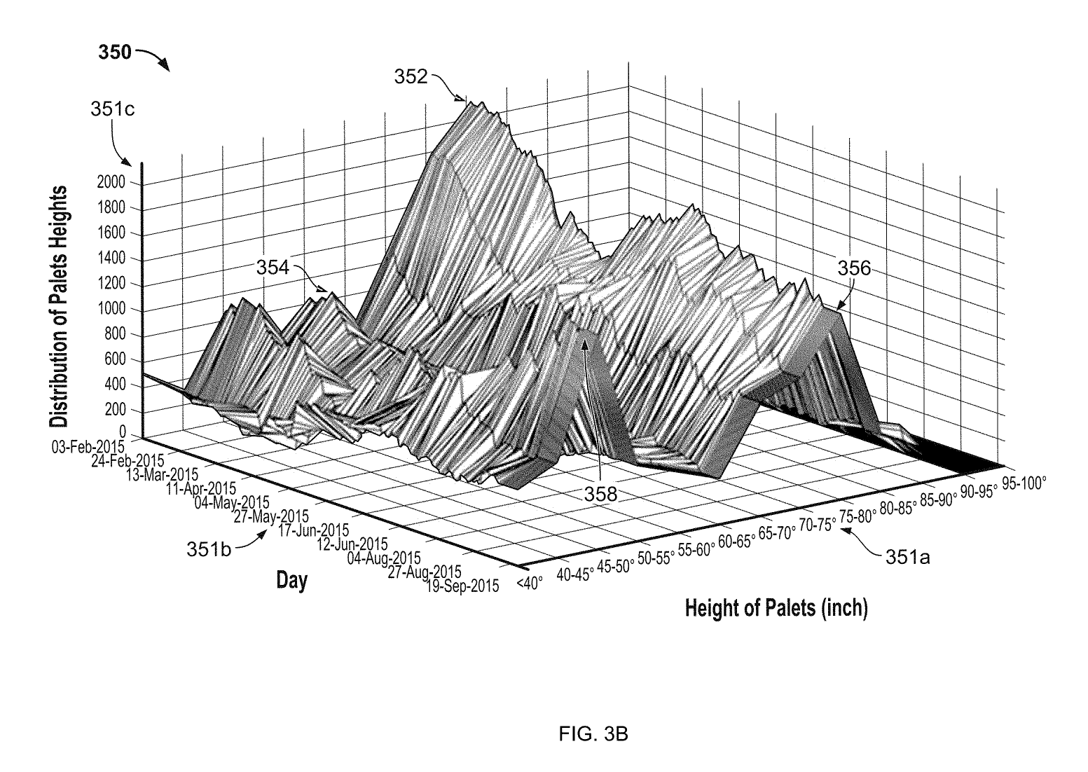

FIGS. 3A-B are graphs that depict example scenarios in which inventory for a storage facility vary over time. The example graphs that are depicted in these figures demonstrate the complexity and difficulty in arriving at an automated warehouse design that will provide an optimal solution for storing fluctuating inventory over time. For example, some automated warehouse designs may be highly effective at storing a steady state of pallets over time, but may not be highly inefficient in processing spikes in pallet volume, making those automated designs unusable to accommodate inventory conditions over time. The systems, devices, and techniques described throughout this document are specifically configured to identify automated warehouse designs that will provide optimal automated solutions over time and across a wide variety of inventory conditions, including accommodating historic/expected spikes in inventory volume.

Additionally, the systems, devices, and techniques described throughout this document are specifically configured to account for and handle the added variability of having pallets from multiple different companies/clients and across multiple different SKUs. For example, some SKUs can have seasonal variability, like produce during harvest and non-harvest times. Additionally, some companies can have variable storage demands over time. Such factors can create added volatility and unpredictability in inbound and outbound inventory for a facility. The systems, devices, and techniques described throughout this document can account for such volatility and uncertainty in identifying an automated warehouse design that will provide an optimal solution across the broad spectrum of variation could be encountered.

Referring to FIG. 3A, an example graph 300 is depicted that plots the number of trucks that are at a warehouse to drop-off or pick-up loads (302) over time (304). As can readily be seen from the graph 300, there is large variation in the volume of trucks over time—ranging from 18 trucks in one day to 1 (or none). That is an 18× variations from the slowest days (1 truck) to the busiest days (18 trucks).

Referring to FIG. 3B, is a three-dimensional graph 350 showing example variation in pallet distributions for a storage facility over time. In particular, the x-axis (351a) for the graph 350 represents the pallet height buckets, the y-axis (351b) represents time, and the z-axis (351c) represents the distribution of pallets at the facility within the pallet buckets. As depicted in this example, the distribution of pallets at this facility changes over time. For example, at a first time depicted in the graph 350, the facility is storing a large number of tall pallets (around the 80″-85″ bucket) as indicated by the spike 352 and a smaller number of shorter pallets (around the 55″-60″ bucket) as indicated by the smaller spike 354. However, these distributions change so that there is nearly the same number of the tall pallets as there are of the shorter pallets at a last time depicted in the graph 350, as indicated by the spike 356 (around the 80″-85″ bucket) being at nearly the same level as the spike 358 (around the 55″-60″ bucket). The systems, devices, and techniques described throughout this document can account for such volatility and uncertainty represented in graphs 300 and 350, by identifying automated warehouse designs that will provide optimal solutions across the broad spectrum of variation could be encountered.

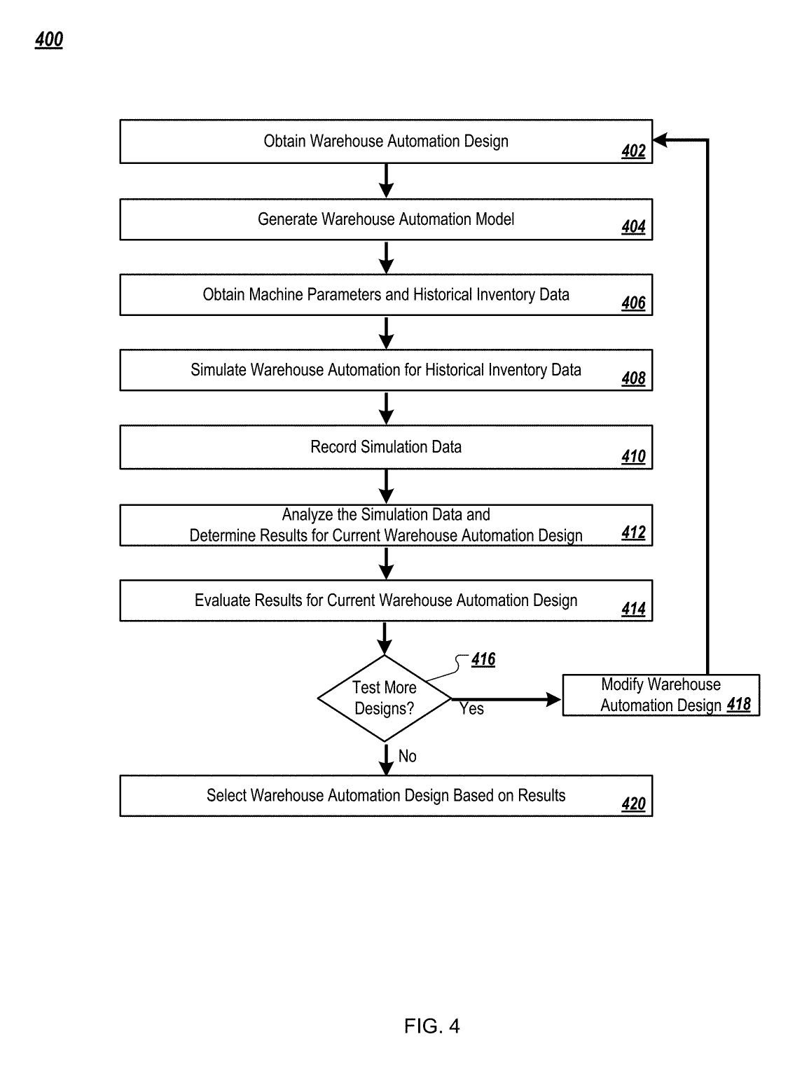

FIG. 4 is a flowchart of an example technique 400 for performing automated warehouse simulations to determine an optimal warehouse automation design. The example technique 400 can be performed by any of a variety of appropriate computing devices, such as the computer system 104 and/or other computing devices/systems.

An automated warehouse design can be obtained (402) and used to generate a warehouse automation model (404). An automated warehouse design can be, for example, an architect or engineers blueprint for the warehouse and its automation components. The warehouse automation model can be a computer-based model that represents the component characteristics, the functional relationship among the components, and the physical relationship among the components within the warehouse. Other details can also be represented in the warehouse automation model. The warehouse automation model can be used to simulate different components of the automated warehouse design transporting pallets within the warehouse.

Machine parameters and historical inventory data can be obtained (406). For example, parameters for the automation components can be used to determine how the automation components behave and operate within the warehouse, such as information identifying acceleration, max speed, delays, capacity, and/or other details. The machine parameters may be included in and/or added to the warehouse automation model, or may be referenced by identifiers for the machines in the warehouse automation model.

The historical inventory data can be, for example, historical inbound and outbound truckloads of pallets, including information identifying pallets within each truck. The historical inventory data can include timestamp information so that realistic use scenarios for the automated warehouse can be simulated, such as spikes in inventory. Additionally and/or alternatively, the historical inventory data can include predictive inventory data that estimates expected inbound and outbound truckloads at various times in the future. Such predictive inventory data can be generated, for example, by analyzing historical inventory data (e.g., machine learning techniques) to identify trends and expected future behavior.

Using the warehouse automation model, the machine parameters, and the historical inventory data use of the automated warehouse design can be simulated for the historical inventory data (408). For example, the historical inventory data can be sequentially simulated as inputs for the automated warehouse design under test, and the warehouse automation model and machine parameters can be used to simulate the transportation and storage of the historical inventory in the automated warehouse design. The simulation can involve recording simulation data (410), such as recording the arrival of pallets at various checkpoints throughout the automated warehouse facility and/or the arrival/departure of trucks at the facility. Using the recorded data, the simulation data can be analyzed and used to determine results for the current warehouse automation design (412). For example, the simulation data can be used to identify time intervals for the place and pick operations and to determine the overall performance of the warehouse automation design.

The results for the current warehouse automation design can be evaluated (414), such as being compared against target performance metrics and/or being compared against the performance of alternate warehouse automation designs that have been simulated. Based on the evaluation, a determination can be made as to whether more designs should be tested (416). If more designs are to be tested (e.g., the current design under test did not meet performance metrics and/or did not perform better than other designs), then the design can be modified (418) and fed back into the technique 400 for another simulation. If no more designs are to be tested (e.g., current design under test met performance metrics, universe of available options has been exhausted, current design performed better than other designs), then a warehouse automation design can be selected to use for the warehouse based on the simulation results (420). For example, a warehouse automation design with a_{—} best simulation result (e.g., most efficient) can be selected.

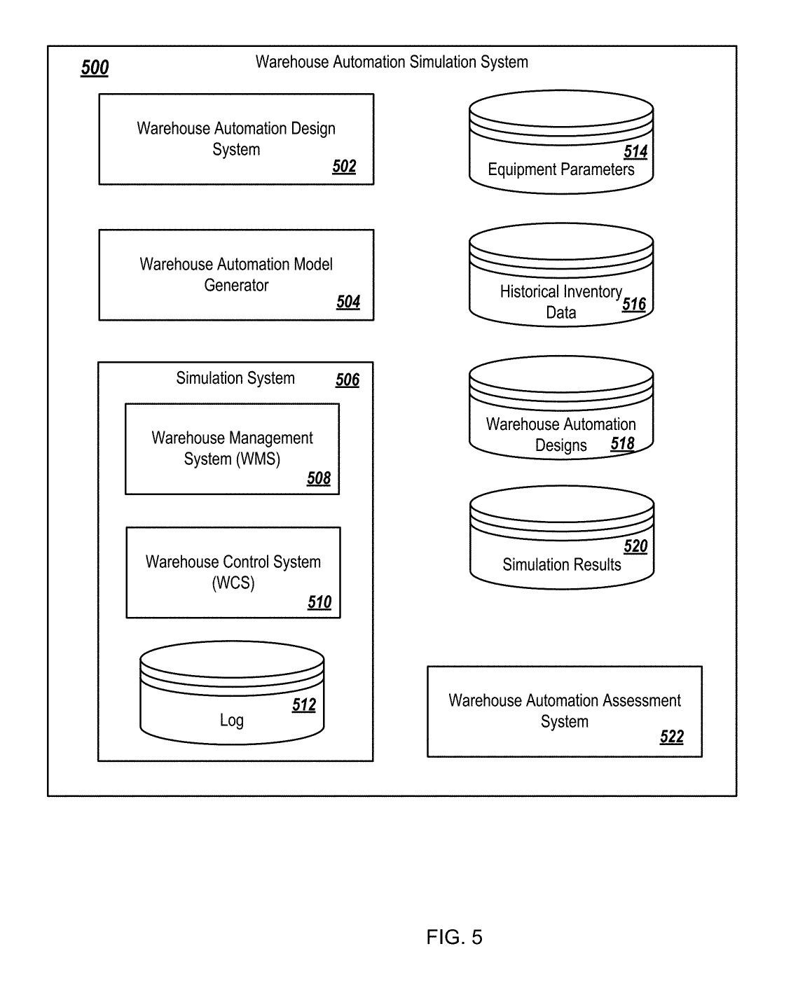

FIG. 5 is an example warehouse automation simulation system 500 that can be used to simulate warehouse designs. The example system 500 can be used to perform some or all of the techniques described throughout this document, such as the technique 400 described above with regard to FIG. 4.

The system 500 includes a warehouse automation design system 502 that can be programmed to determine automation warehouse design for a given warehouse space. For example, the system 502 can automatically select and place automation components are appropriate locations within a warehouse to provide automation services. The warehouse designs generated by the system 502 can be provided to the warehouse automation model generator 504, which can take warehouse designs and convert them into computer-readable models for simulating warehouse automation.

The warehouse models generated by the system 504 can be provided to and used by the simulation system 506 to simulate use of an automated warehouse design. The simulation system 506 includes a WMS 508 that can direct the high-level flow of pallets within the warehouse, such as identifying storage locations for pallets, determining paths through the automated system for delivering the pallet to a storage location, identifying pallets to be retrieved, and assigning trucks to particular doors/bays in the warehouse. The simulation system 506 also includes a warehouse control system (WCS) 510 that translates the high-level directions from the WMS 508 into specific control commands that are provided to the automated components within the warehouse, such as determining a sequence of control operations provided to the conveyor system. The system 506 also includes database 512 storing logs of various actions performed during simulations, including records of pallets arriving at various checkpoints within the automated warehouse.

The system 500 further includes a warehouse automation assessment system 522 that can analyze the simulation log 512 to determine an overall result for the simulation and to evaluate whether the automation design was a good fit for the warehouse, the specific inventory data, and the automation components used in the design. The system 522 can additionally identify specific features within the automation design that may have caused one or more inefficiencies, such as bottlenecks caused by too few conveyors or cranes, and solutions to remedy the inefficiencies.

The system 500 includes a variety of additional databases 514-520 to aid the components 502-506 and 522 in performing their respective operations. The equipment parameters 514 stores parameters for automation equipment (e.g., machines) that are available for incorporation into the automated warehouse design. The historical inventory data 516 stores historical and/or projected inbound and outbound trucks with pallets for the warehouse. The warehouse automation designs 518 stores warehouse automation designs that have and/or will be simulated and tested by the system 500. The simulation results 520 stores the results for the simulations so that they can be compared against each other and against one or more metrics to aid in identifying an optimal solution.

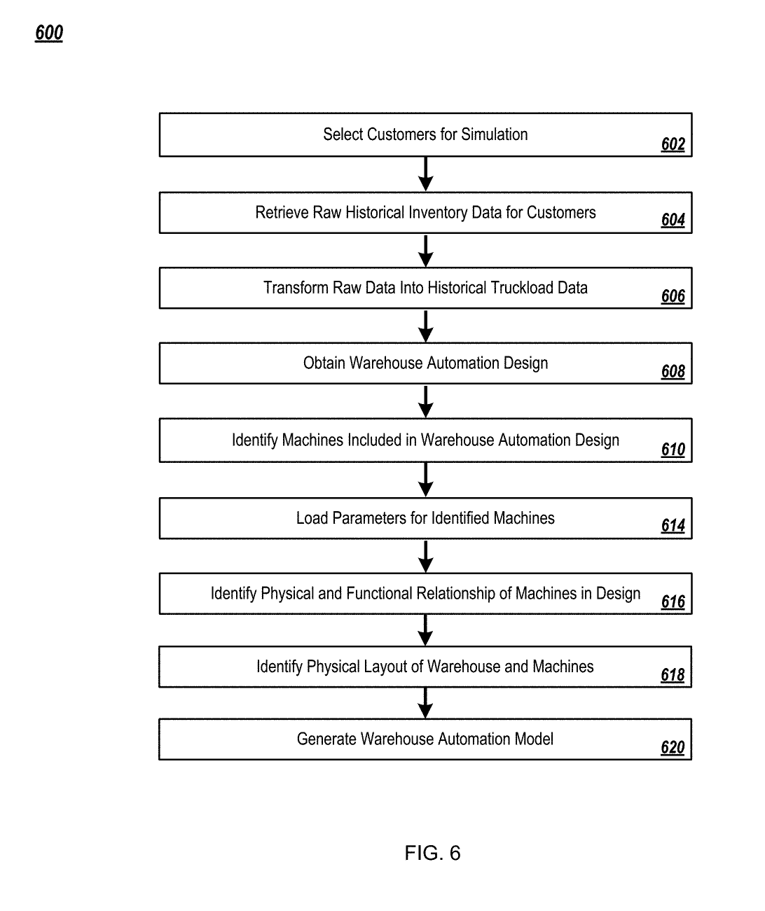

FIG. 6 is a flowchart of an example technique 600 for generating a warehouse automation model. The example technique 600 is, for example, a more detailed description of the steps 402-406 described above with regard to FIG. 4. The technique 600 can be performed by any of a variety of appropriate systems, such as the system 500 described above with regard to FIG. 5.

Customers (e.g., companies, clients) can be selected for inclusion in the simulation (602). For example, current customers for a warehouse for which automation is being simulated can be selected. In another example, customers who are projected to use a new warehouse that has yet to be constructed can be selected. In a further example, current customers and additional new customers who are being evaluated for possible inclusion at the warehouse can be selected. Other variations are also possible.

Raw historical inventory data for the selected customers can be retrieved (604) and transformed into truckload data (606). For example, the raw inventor data can be provided on a pallet-by-pallet basis. However, to simulate how and when pallets will arrive at the warehouse, the data should be centered around the mode of transportation for delivering the pallets (e.g., trucks, trains, boats) to the warehouse. Accordingly, the raw data can be transformed from pallet records to truck-based records that group all pallets according to the truckload carrying the pallets.

A warehouse automation design can be obtained (608) and the automation machines identified in the design can be identified (610). For example, the specific make and model of conveyors, cranes, and carts can be identified from the automated design. These identifications can be used to load parameters for the identified machines (614), such as the speed, acceleration, delay, capacity, and/or other parameters for the machines. The parameters can be incorporated into the warehouse automation model. The warehouse automation design can additionally be used to identify physical and functional relationships among the machines in the design (616), such as the proximity of components to each other, functional/physical connections between the components, and/or other details. The physical layout of the warehouse and machines in the warehouse can additionally be identified from the automation design (618), such as identifying the location of components within the warehouse. Based on these factors, the warehouse automation model can be generated for use in the simulation (620).

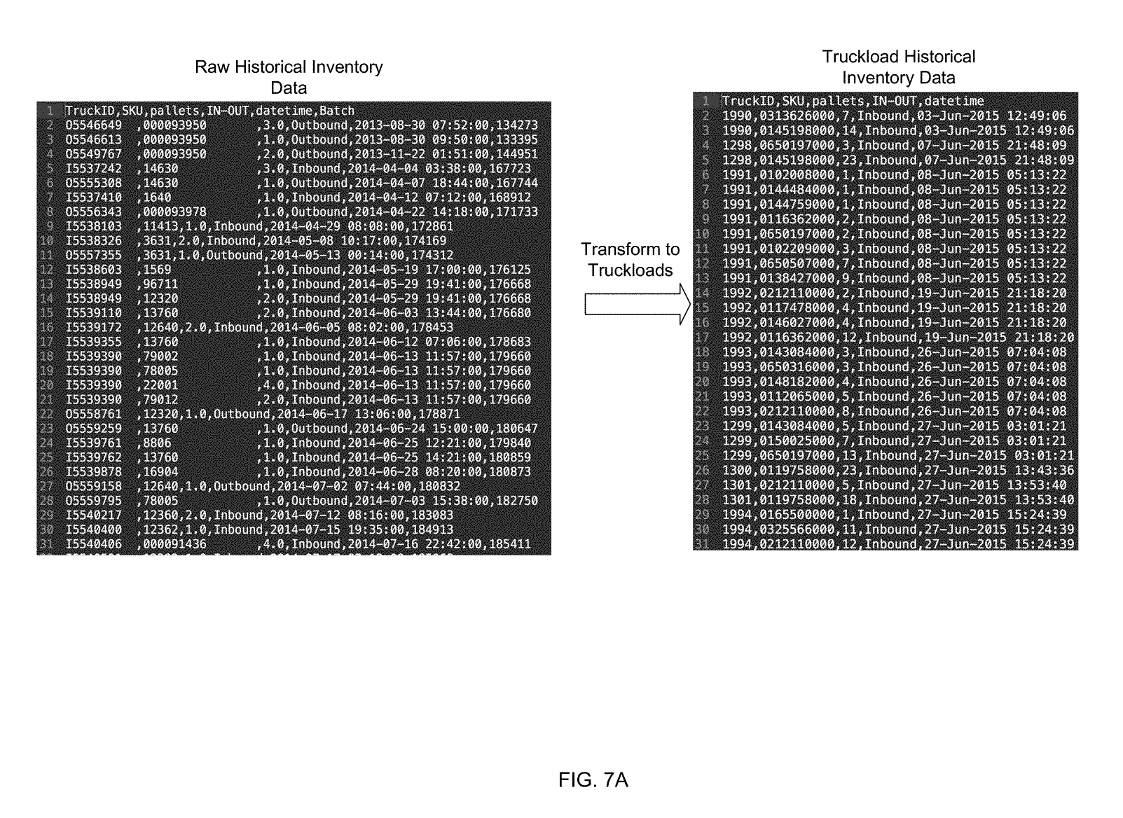

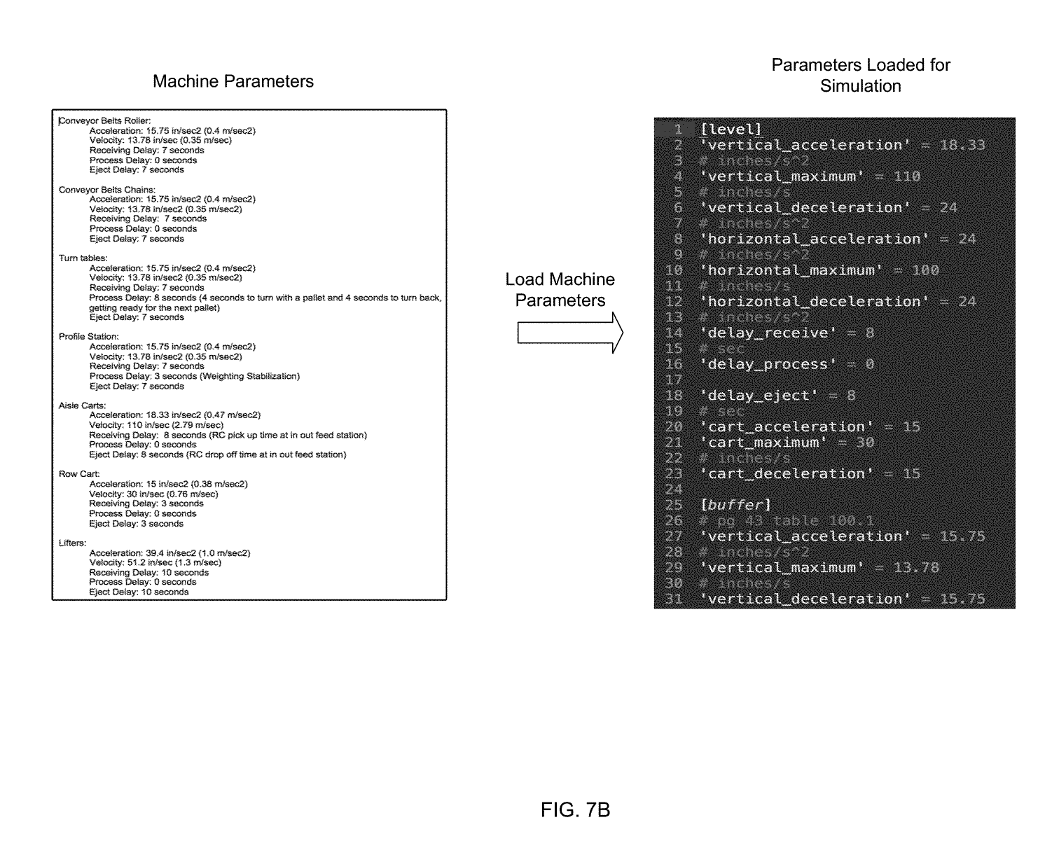

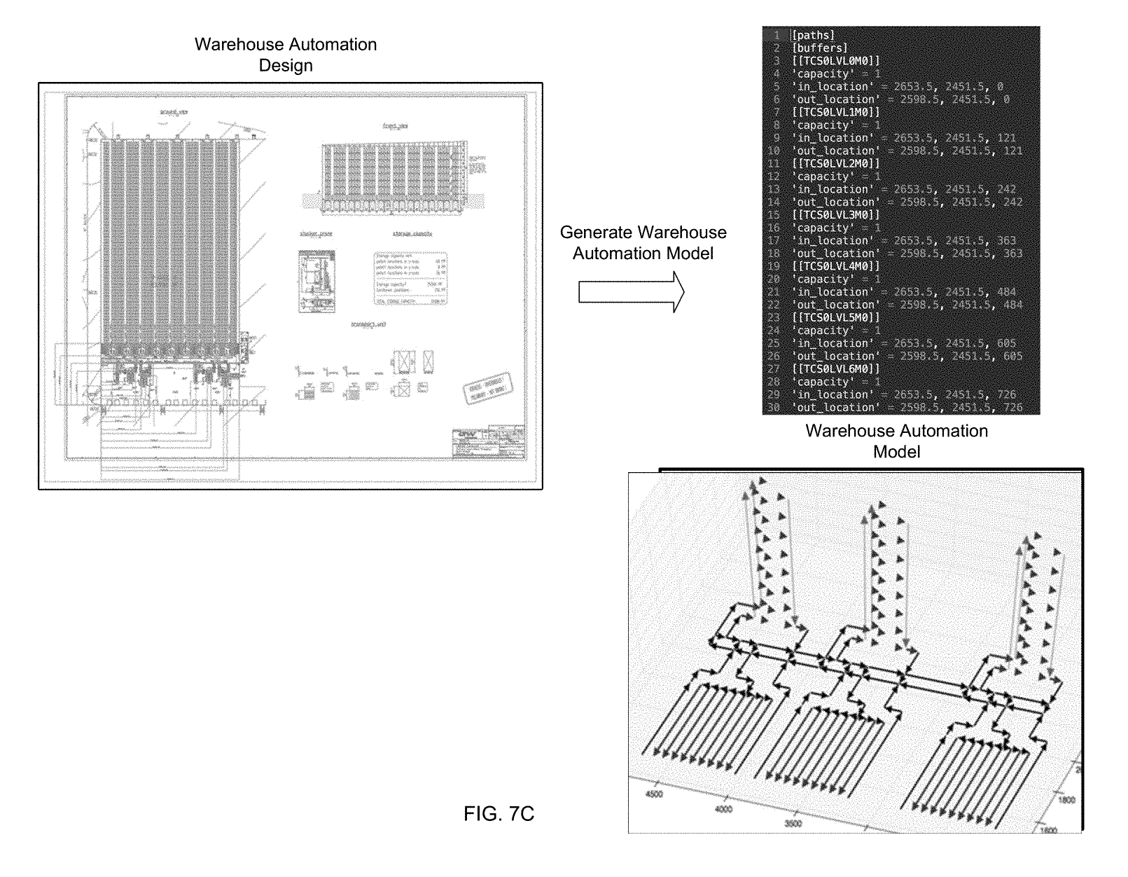

FIGS. 7A-C depict example data transformations that are performed as part of the technique 600 to generate a warehouse automation model. FIG. 7A depicts an example of raw historical inventory data being transformed into truckload historical inventory data, as described above with regard to step 606. FIG. 7B depicts an example of machine parameters being loaded for use in the simulation, as described above with regard to step 614. FIG. 7C depicts an example of a warehouse automation design being used to generate a warehouse automation model, as described above with regard to steps 608-620.

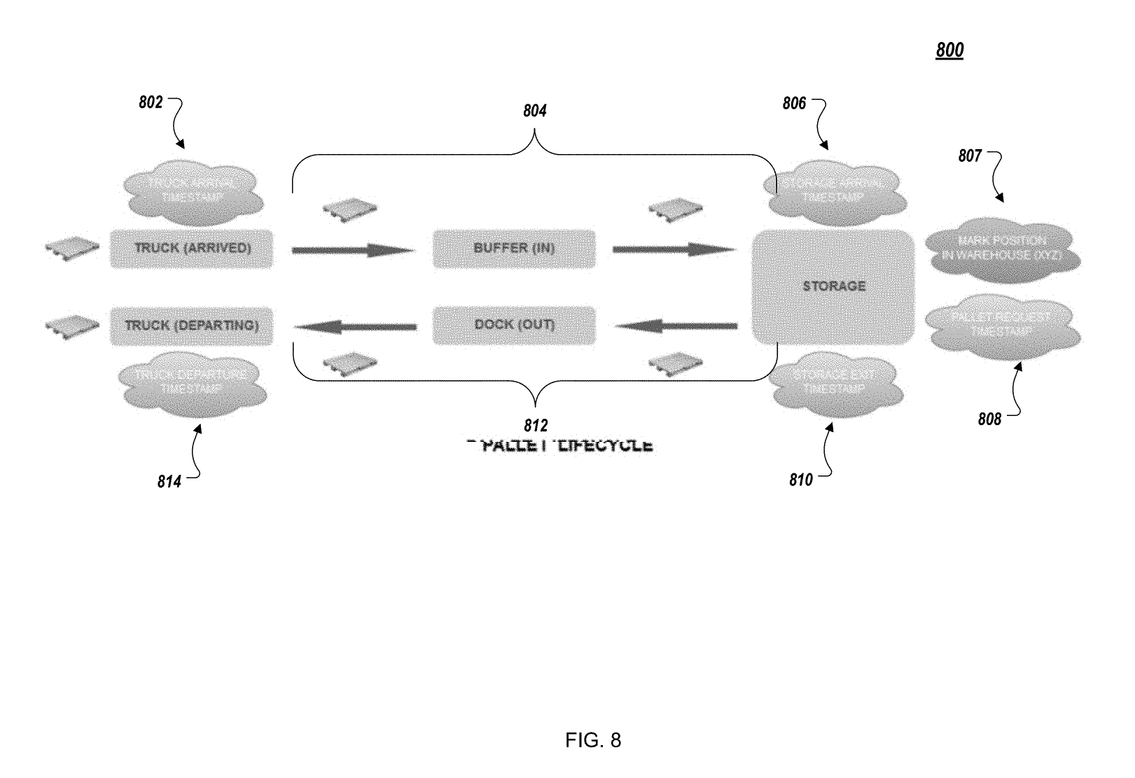

FIG. 8 is a conceptual diagram 800 depicting automated warehousing actions that are simulated and data that is recorded as part of the simulation. The simulation and data recording that is depicted can be performed, for example, by the system 500 using the technique 400, as described above. Other systems and techniques can also be used. As described above with regard to FIG. 2A, the data can be recorded in any of a variety of formats, such as being recorded using a coordinate-based system that identifies the coordinate within a simulated warehouse where an event occurred, an identifier for an object to which the event pertains, and a timestamp within the simulation for when the even occurred.

A first action 802 that is simulated and recorded is a truck arriving at the warehouse. The record generated for this can be a timestamp in the simulation for the truck's arrival. A next action 804 is the transport of each pallet within the truck to storage locations within the warehouse that are designated for each pallet. This action can be simulated using the automated warehousing components in the warehouse automation design that is being tested, and the duration of this action can be indicated by the difference between a timestamp when the pallet left the truck to when it arrived at the storage location, which is a next action 806. The storage location (position) for the pallet can be marked 807, which can conclude the place simulation for a pallet.

Once placed at a storage location, a simulation of the pallet being retrieved from that location can be performed. Starting with action 808, the request for the pallet issued to the system can be recorded with a timestamp. The next action 810 is the actual (simulated) retrieval and exit of the pallet out of the storage racks, which causes the pallet to travel over the automated components to the departing truck, as indicated by action 812. The final action 814 in retrieving the pallet is loading it onto the departing truck, which can be additionally be accompanied by a corresponding timestamp.

The table below details the example historical inventory data (“real data”) that is used to drive the simulation and the example actions that are simulated, such as those described above with regard to FIG. 8:

TABLE 1

| | Simulated Actions |
|---|---|
| From Real Data: | (Listed major actions, but not limited to): |
| Trucks time into the facility | The time the pallet gets into the facility |
| Trucks ID's | The time for pallets on a conveyor or other |
| | mechnacal equiptment |
| The amount of pallets in the | Time within the storage area |
| truck | |
| The pallets SKUs | The time it was requested (as given by |
| | outbound truck time) |
| Inbound or Outbound | Time it took to get out of the facility |
| | The time the truck pulled out of the dock |

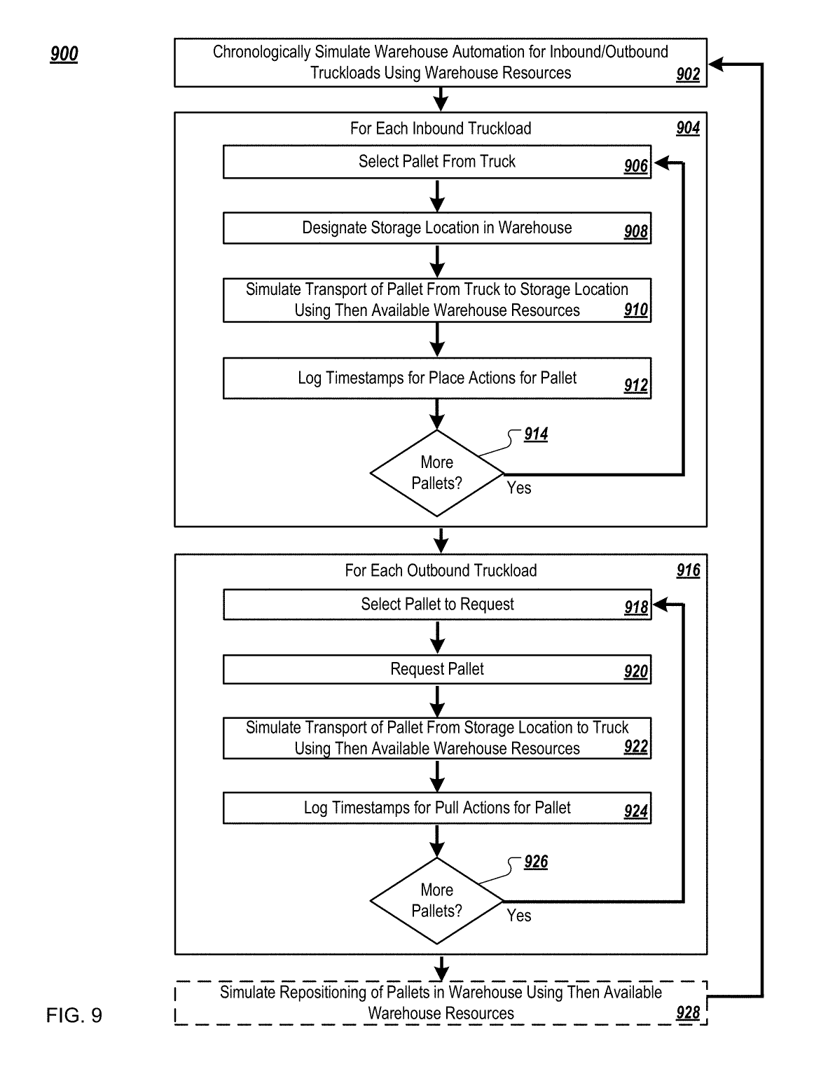

FIG. 9 is a flowchart of an example technique 900 for simulating use of a warehouse automation design. The example technique 900 can be performed, for example, at step 408 of the technique 400, and can be performed by any of a variety of appropriate systems, such as the system 500.

Warehouse automation for inbound/outbound truckloads can be simulated chronologically using the warehouse resources for the automated warehouse design (902). For example, the historical truckload data (step 606) can be evaluated chronologically from oldest to newest historical truckload to arrive at the automated warehouse. The simulation can be performed using the warehouse resources—automated warehouse components and other warehouse components (e.g., forklift, dock, doors/bay)—whereby pallets from truckloads are each simulated as being placed and pulled using then available resources for the warehouse. For instance, if there are five forklifts that are available for the warehouse and they are all occupied with other tasks when a pallet is available to be unloaded from a truck, then the simulation will wait to unload the pallet until one of the forklifts is available and has traveled along the dock to the door/bay where the pallet is located. Similarly, if all of the conveyors are occupied (none available) when a pallet is ready to enter the conveyors for transport to or from the racks, then the simulation can cause the pallet to wait to enter the conveyors until one is available.

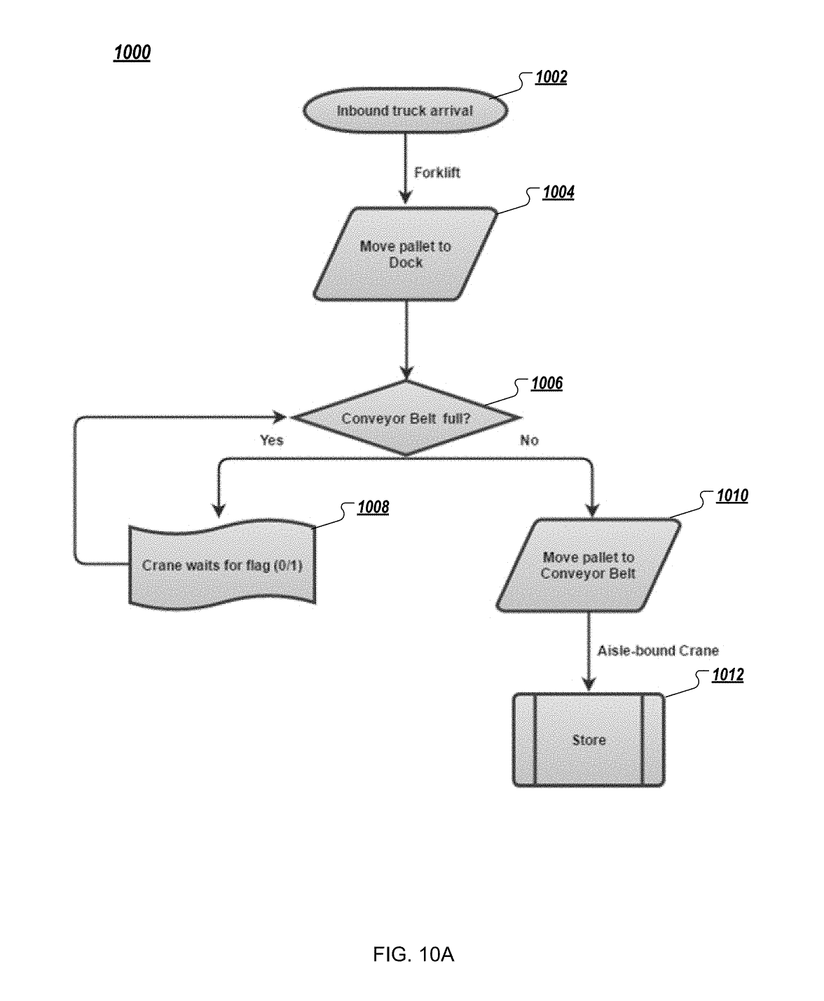

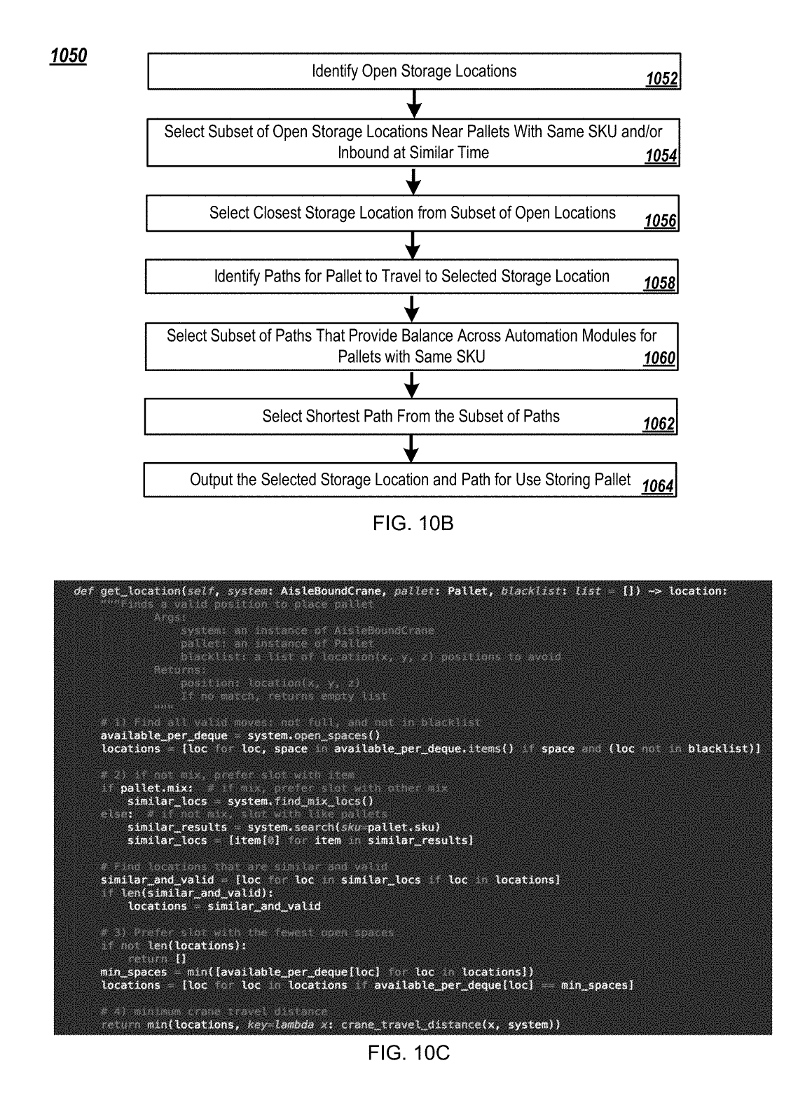

The process for simulating each inbound truckload (904) and for simulating each outbound truckload (916) involves simulating each pallet transport in or out of the truck. For example, for each inbound truckload a pallet is selected from the truck (906) and then a storage location (rack location) in the warehouse where the pallet is to be stored can be designated (908). An example process for designating a storage location for an inbound pallet is described below with regard to FIGS. 10B-C. For example, control logic can be used to identify a storage location that will provide a shortest path for storing the pallet, and can be used to identify such a shortest path through the warehouse design under test, which can provide a shortest time to store the pallet in the warehouse. Such control logic can identify and route pallets to appropriate locations in the warehouse in an optimally efficient manner, and can be used as part of an automated warehouse simulation to simulate the movement of pallets (from historical inventory data) across an automated warehouse design under test, as described below with regard to FIG. 10A. For instance, given a warehouse design under test, control logic can be used to identify an optimally efficient storage location for the pallet (e.g., location permitting the pallet to be inserted into the rack faster and with less rearranging of pallets) and a route along the various modules in the design under test, and to simulate the peculiar movement of the pallet along the route.

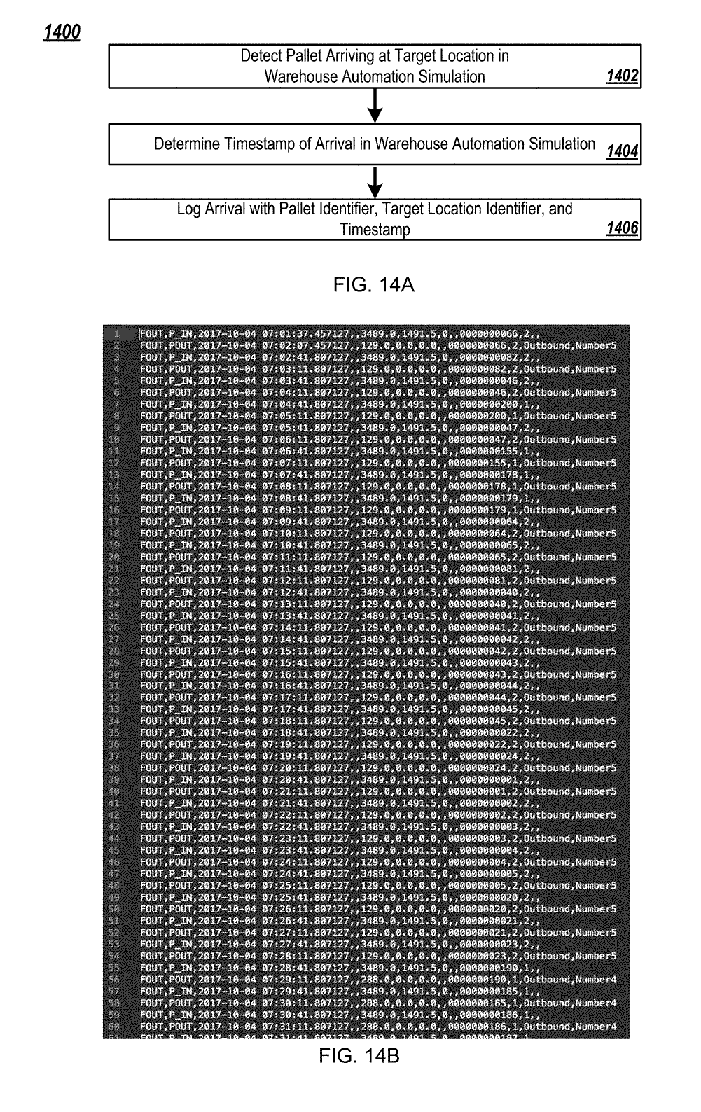

With the storage location designated, the transport of the pallet from the truck to the storage location using then available warehouse resources can be simulated (910). An example process for simulating the transport of the pallet to its designated storage location is described below with regard to FIG. 10A. Timestamps for place actions for the pallet as it is transported (and arrives at checkpoints along its path) from the truck to the storage location can be logged (912). An example process for logging such actions is described below with regard to FIG. 14. If there are more pallets in the truck to be unloaded (914), then the process 906-912 can be repeated for each of those pallets until the truck has been fully unloaded. The step 904 can be repeated for each inbound truckload when, according to progression of time in the simulation, the truckload is set to arrive at the warehouse.

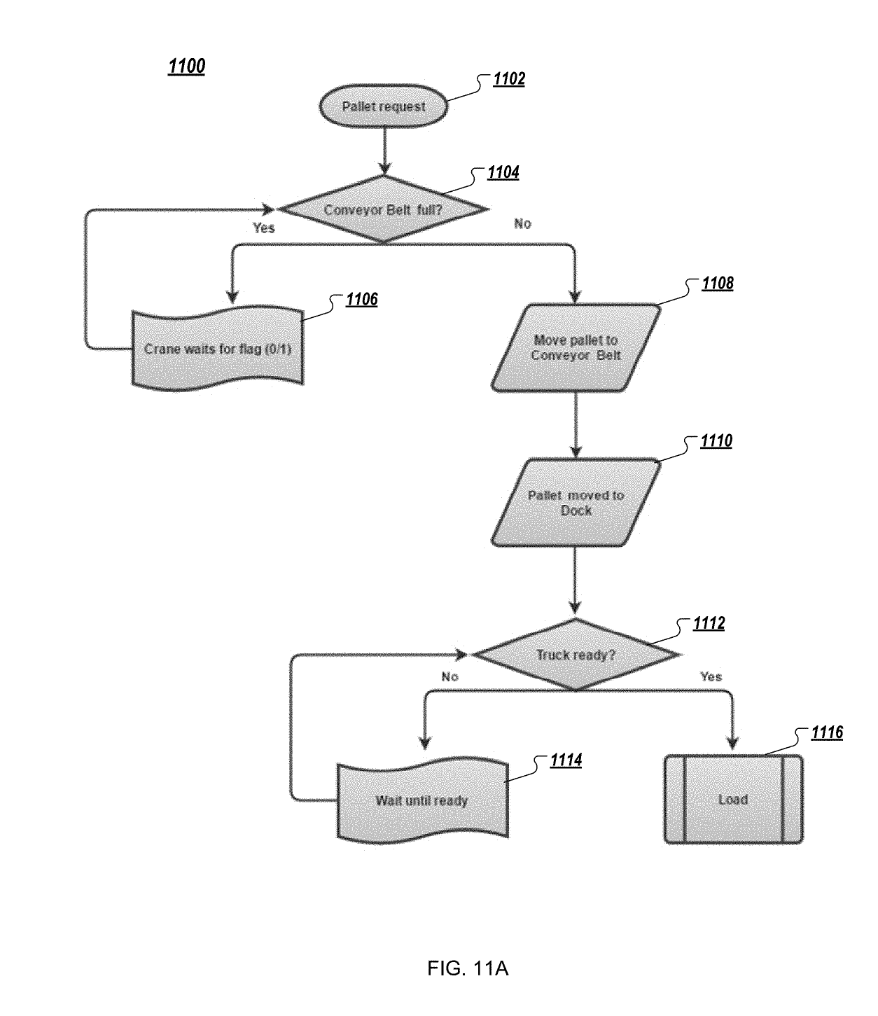

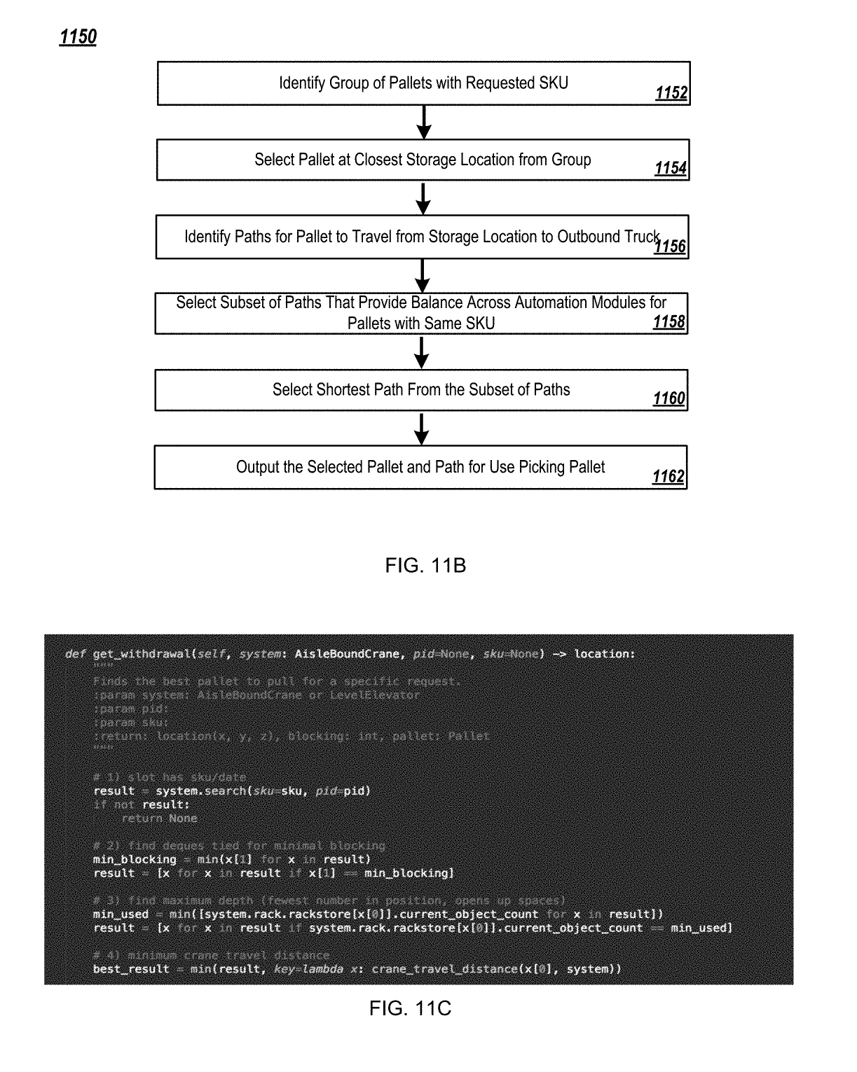

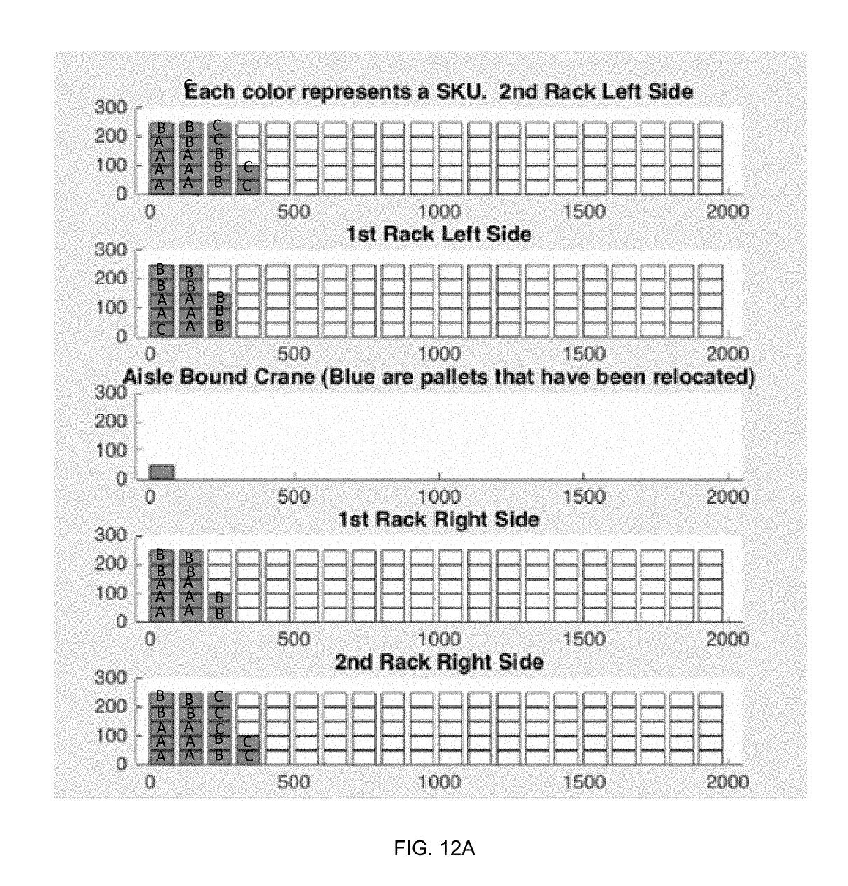

Similar to the unloading of inbound trucks, the transport of each pallets in each outbound truck can be simulated from its storage location to the outbound truck (916), which can involve selecting a pallet to request from among a group of similar/same pallets in the warehouse (918). For example, if the pick request calls for a pallet with a particular SKU (and for a particular customer), the group of pallets that each have that SKU (and particular customer) can be identified and one of the pallets from that group can be selected. Example processes for selecting a pallet for a request are described below with regard to FIGS. 11B-C. For example, control logic can be used to identify a particular pallet from a group of pallets with a requested SKU that will provide a shortest path from the warehouse racks to the truck and to identify such a shortest path through the automated warehouse design under test, which can provide a shortest time to satisfy the pallet request. Such control logic can identify and route appropriate pallets from locations in the warehouse to trucks in an optimally efficient manner, and can be used as part of an automated warehouse simulation to simulate the movement of pallets (from historical inventory data) across an automated warehouse design under test, as described below with regard to FIG. 11A. For instance, given a warehouse design under test, control logic can be used to identify an optimally efficient pallet to select for servicing a pallet request (e.g., pallet able to be removed from the rack faster and with less rearranging of pallets) and a route for moving the pallet along the various modules in the design under test to a corresponding truck, and to simulate the peculiar movement of the pallet along the route.

A request can be issued for retrieving the selected pallet (920) and the transport of the pallet from the storage location to the truck can be simulated using then available warehouse resources (922). An example process for simulating the pick and transport of the pallet to the truck is described below with regard to FIG. 11A. Timestamps for the pull actions for the pallet can be logged as the pallet travels from its storage location to the truck (924). An example process for logging timestamps is described below with regard to FIG. 14. The steps 918-924 can be repeated for each pallet to be loaded onto the outbound truck until all pallets for the outbound truckload have been simulated (926).

In some implementations, pallets within the warehouse can be repositioned within the racks at various points in time and those repositioning operations can be simulated using then available resources (928). For example, as pallets are picked from a warehouse, spots that are closer to the front of the warehouse can open up. During periods of downtime, such as times when no inbound or outbound trucks are scheduled for the warehouse, the automated warehouse system can be controlled to automatically reposition pallets located further ways from the front of the warehouse to open positions closer to the front of the warehouse.

The steps 902-928 can be repeatedly performed until all inbound and outbound truckloads have been simulated, and simulation logs for each of the pallets in the trucks have been generated.

FIGS. 10A-C depict example techniques for simulating inbound pallet movements to storage locations within the warehouse. The example techniques can be performed, for example, as part of the inbound processing 904 in the technique 900, and can be performed by any of a variety of appropriate systems, such as the system 500.

Referring to FIG. 10A, an example technique 1000 for simulating the transport of an inbound pallet from an inbound truck to a storage location in the warehouse is presented. An inbound truck arrives at the warehouse (1002) and a pallet from the truck is simulated as being moved to the dock by a forklift (1004). This simulation can involve, for example, using the acceleration and max travel speed for the forklift and the distance from the pallet pickup location to the conveyor belt to determine a position of the pallet over time as it travels from the truck to the conveyor belt. An evaluation of whether the conveyor belt is full (whether it is then available to be used for the pallet) can be made (1006). If the conveyor belt is full, then a wait operation can be repeatedly simulated (1008) until the conveyor belt is not full (available). Once available, the pallet can be moved onto the conveyor belt and simulated as travelling along the automated components (1010) and stored at the designated storage location for the pallet (1012). The simulated position of the pallet travelling along the automated components can use the acceleration, maximum velocity, deceleration, and other parameters, for example, for the conveyor belt, crane, and cart over time.

Referring to FIG. 10B, a flowchart of an example technique 1050 providing storage location selection logic. The example technique 1050 can be used, for example, to select an optimal open storage location and an optimal path to reach the storage location for the pallet. Open storage locations are identified (1052) and a subset of the open storage locations near pallets with the same SKU and/or that were inbound at the same time (e.g., from the same truckload) can be selected (1054). For example, efficiencies can be gained by storing pallets that will be placed and pulled near each other in the warehouse. A closest storage location from among the subset of open locations can be selected (1056). For example, a closest storage location to the position of the pallet in the inbound truck can be selected. In another example, a closest storage location to the front of the warehouse can be selected. In another example, a closest storage location that will reduce the rearrangement of pallets within the storage area and that will permit pallets to be retrieved more quickly for outbound delivery can be selected.

With the storage location selected, the optimal path for reaching the storage location can be identified. The set of possible paths along which the pallet can travel to the selected storage location can be identified (1058). This identification can take into account the current paths that may be occupied by other pallets and, therefore, be unavailable. A subset of the possible paths can be selected that will provide balance across automation modules for pallets with the same SKU (1060). For example, it can be beneficial to concurrently use as many redundant automation components (e.g., conveyors, cranes) at the same time, which can reduce the aggregate storage time for the pallets even though one of the paths may not be the shortest overall path for a particular pallet. A shortest path from among the selected subset of possible paths can be selected (1062). A shortest overall path can be selected and/or a path with shortest component parts (e.g., shortest path through an area with significant temperature deviation from the truck and/or warehouse temperature) can be selected. For example, with cold storage warehouses and providing frozen storage for pallets, a path can be selected that (1) first minimizes the length of travel for the pallet to move from a truck to the frozen storage area of the warehouse (e.g., minimize the distance through the dock area of the warehouse) and (2) second minimizes the distance from the point at which the pallet enters the frozen storage area of the warehouse to the storage location for the pallet. Such a configuration can minimize the time that pallets spend in an area with a significant temperature difference from the pallet's target temperature, with maximizing the time that the pallets spend within a temperature that is at or around the pallet's target temperature. Other techniques and factors for selecting a shortest path are also possible. Once determined, the selected shortest path can be output along with the storage location for use running the simulation for the pallet (1064), as described above with regard to FIG. 10A.

Referring to FIG. 10C, example code for selecting an optimal storage location for an inbound pallet (steps 1052-1056) is depicted.

FIGS. 11A-C depict example techniques for simulating outbound pallet movements to storage locations within the warehouse. The example techniques can be performed, for example, as part of the outbound processing 916 in the technique 900, and can be performed by any of a variety of appropriate systems, such as the system 500.

Referring to FIG. 11A, an example technique 1100 for simulating the transport of an outbound pallet from a storage location in the warehouse to an outbound truck is presented. A pallet request is received as part of the simulation (1102), such as being triggered when the outbound truck arrives at the warehouse, and an evaluation of whether the conveyor belt is full (whether it is then available to be used for the pallet) can be made (1104). If the conveyor belt is full, then a wait operation can be repeatedly simulated (1106) until the conveyor belt is not full (available). Once available, the pallet can be simulated as travelling along the automated components by being moved through the automated system (cart, crane) and onto the conveyor belt (1108). The simulated position of the pallet travelling along the automated components can use the acceleration, maximum velocity, deceleration, and other parameters, for example, for the conveyor belt, crane, and cart over time. The pallet as being moved onto the dock (1110) and a determination can be made as to whether the truck is ready to receive the pallet (1112). If the truck is not available at that time, then a wait operation can be repeatedly simulated (1114) until the truck is available. Once available, the pallet can be simulated as travelling across the dock via a forklift and loaded onto the outbound truck (1116). This simulation can involve, for example, using the acceleration and max travel speed for the forklift and the distance from the pallet pickup location on the conveyor belt to the outbound truck to determine a position of the pallet over time as it is loaded onto the truck.

Referring to FIG. 11B, a flowchart of an example technique 1150_{—} providing pallet selection logic is presented. The example technique 1150 can be used, for example, to select an optimal pallet (from among multiple pallets that could satisfy a pick request) and to determine an optimal path along which the pallet can travel to arrive at the outbound truck. A group of pallets that satisfy the requested SKU can be identified (1152) and, from among this group, a pallet that is the closest storage location can be selected (1154). For example, a pallet at a closest storage location to the outbound truck can be selected. In another example, a pallet at a closest storage location to the front of the warehouse can be selected.

With the pallet selected, the optimal path for the pallet to travel to the outbound truck can be identified. The set of possible paths along which the pallet can travel to the outbound truck can be identified (1156). This identification can take into account the current paths that may be occupied by other pallets and, therefore, be unavailable. A subset of the possible paths can be selected that will provide balance across automation modules for pallets with the same SKU (1158). For example, it can be beneficial to concurrently use as many redundant automation components (e.g., conveyors, cranes) at the same time, which can reduce the aggregate storage time for the pallets even though one of the paths may not be the shortest overall path for a particular pallet. A shortest path from among the selected subset of possible paths can be selected (1160). Similar to the description above with regard to step 1062, a shortest overall path can be selected and/or a path with shortest component parts (e.g., shortest path through an area with significant temperature deviation from the truck and/or warehouse temperature) can be selected. For example, with cold storage warehouses and providing frozen storage for pallets, a path can be selected that (1) first minimizes the length of travel for the pallet to move from a frozen storage area of the warehouse to a truck for the pallet (e.g., minimize the distance through the dock area of the warehouse) and (2) second minimizes the distance from the pallet's storage location to the point at which the pallet exits the frozen storage area of the warehouse to be transported to the truck. Such a configuration can minimize the time that pallets spend in an area with a significant temperature difference from the pallet's target temperature, with maximizing the time that the pallets spend within a temperature that is at or around the pallet's target temperature. Other techniques and factors for selecting a shortest path are also possible. Once determined, the selected shortest path can be output along with the selected pallet for use running the simulation for the pallet (1162), as described above with regard to FIG. 11A.

Referring to FIG. 11C, example code for selecting an optimal pallet to satisfy a pick request (steps 1152-1154) is depicted.

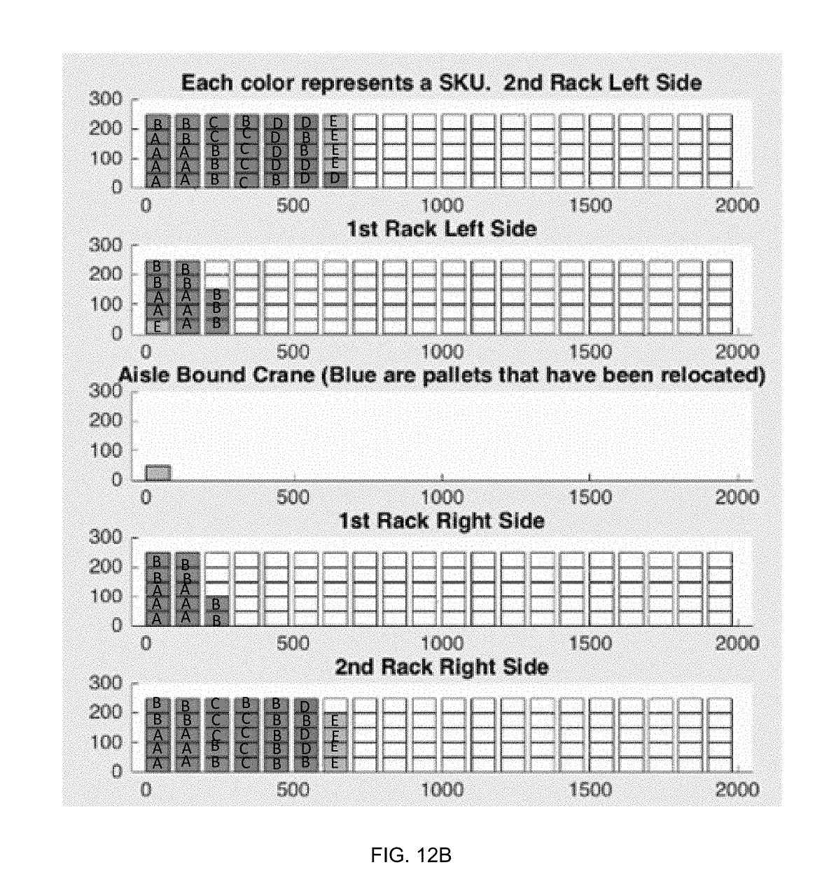

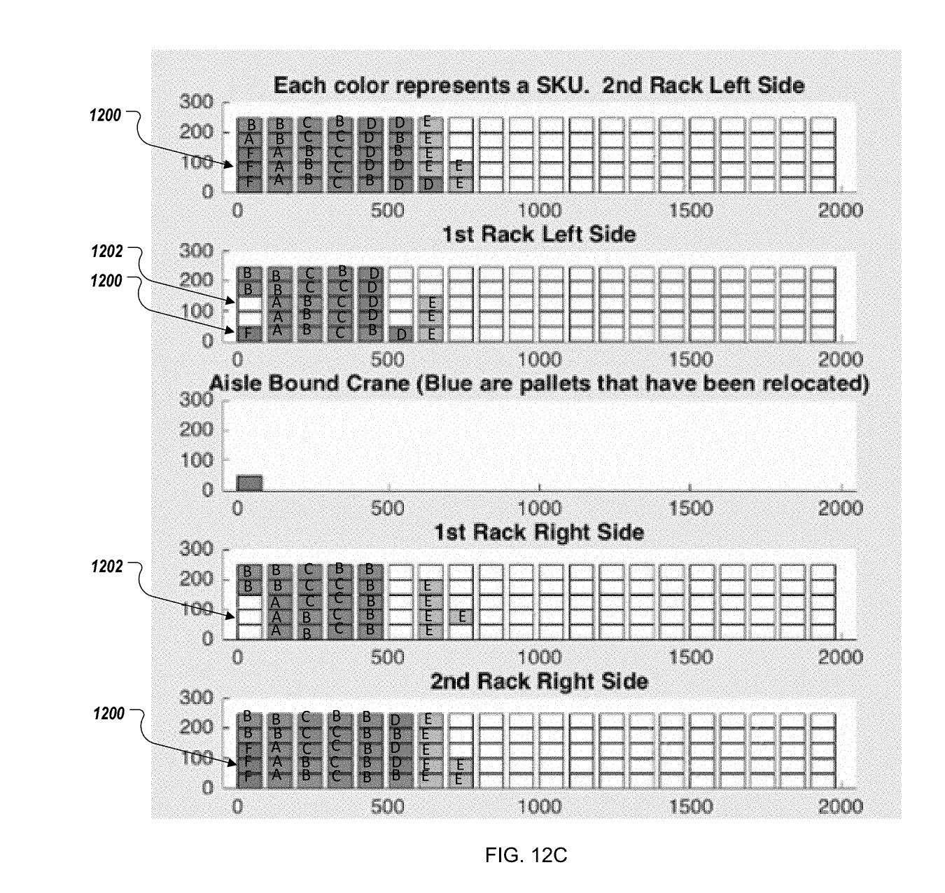

FIGS. 12A-C depict the example simulation of pallets with different SKUs being stored in and removed from racks in a warehouse over time. The examples depict pallets with example SKUs A-F being slotted into the racks and removed over time. The example simulation can be performed using the techniques and systems described throughout this document, such as the technique 400. Rack locations selected for individual pallets to be stored at can be determined using the technique 1050, for example. Pallets that are selected_{—} to satisfy pick requests can be selected using the technique 1150, for example.

Referring to FIG. 12A, pallets with the same SKUs A-C are stored at locations near other pallets with the same SKU, and are stored at the closest locations (locations near the front of the warehouse, which in this example is the left side of the racks). Referring to FIG. 12B, which depicts the simulation further along in time, pallets with additional SKUs D-E have been added to the racks and, again, are stored at locations near other pallets of the same SKU and near the front of the warehouse (closer locations are selected).

Referring to FIG. 12C, which depicts the simulation further in the future from FIG. 12B, some of the originally stored pallets with SKU A have been picked, leaving either openings that have been filled with newly slotted pallets 1200 or that remain open 1202. As indicated by this example, the pick logic causes a pallet that is closest from among a group of pallets with the same SKU to be selected. For example, nearly all of the SKU A pallets have been picked from the first column, yet the second column still contains SKU A pallets. This pick logic provides a variety of benefits, such as reducing the time for each automated pick operation to be performed (by selecting a closest pallet) and also leaving open a close slot open for a new pallet, thereby reducing the time for an automated place operation to be performed.

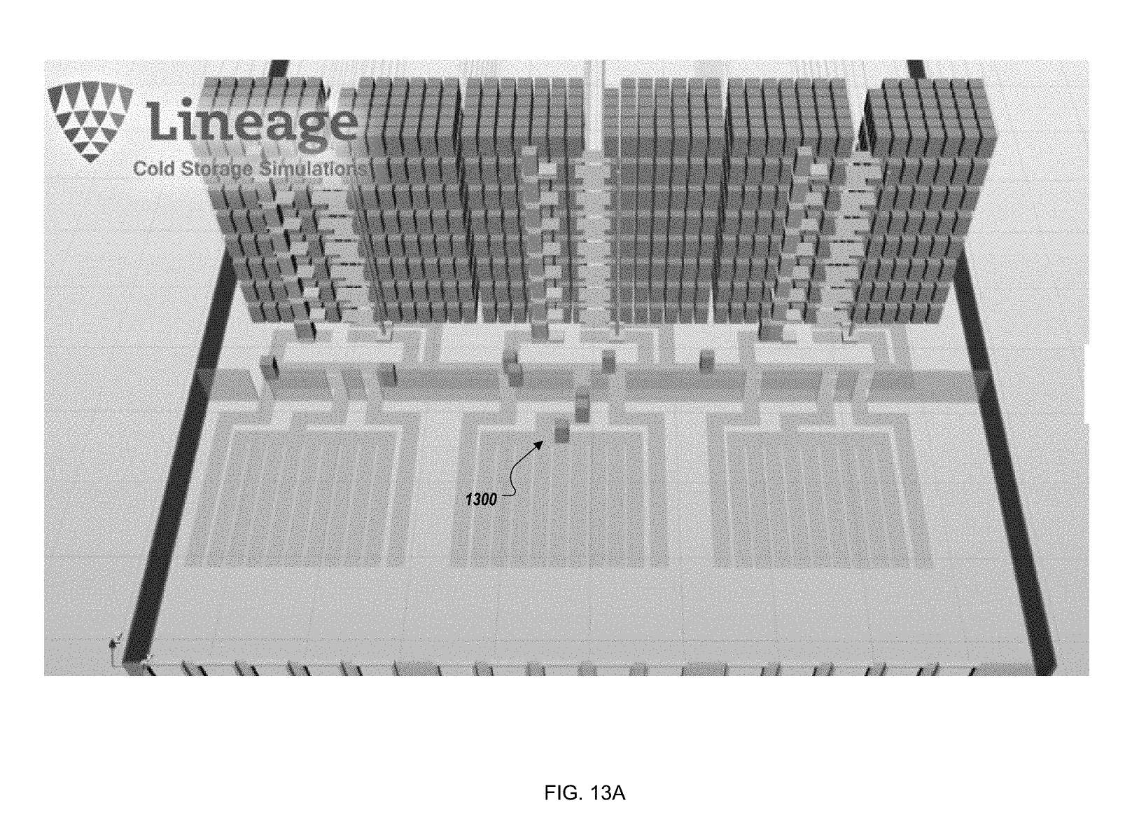

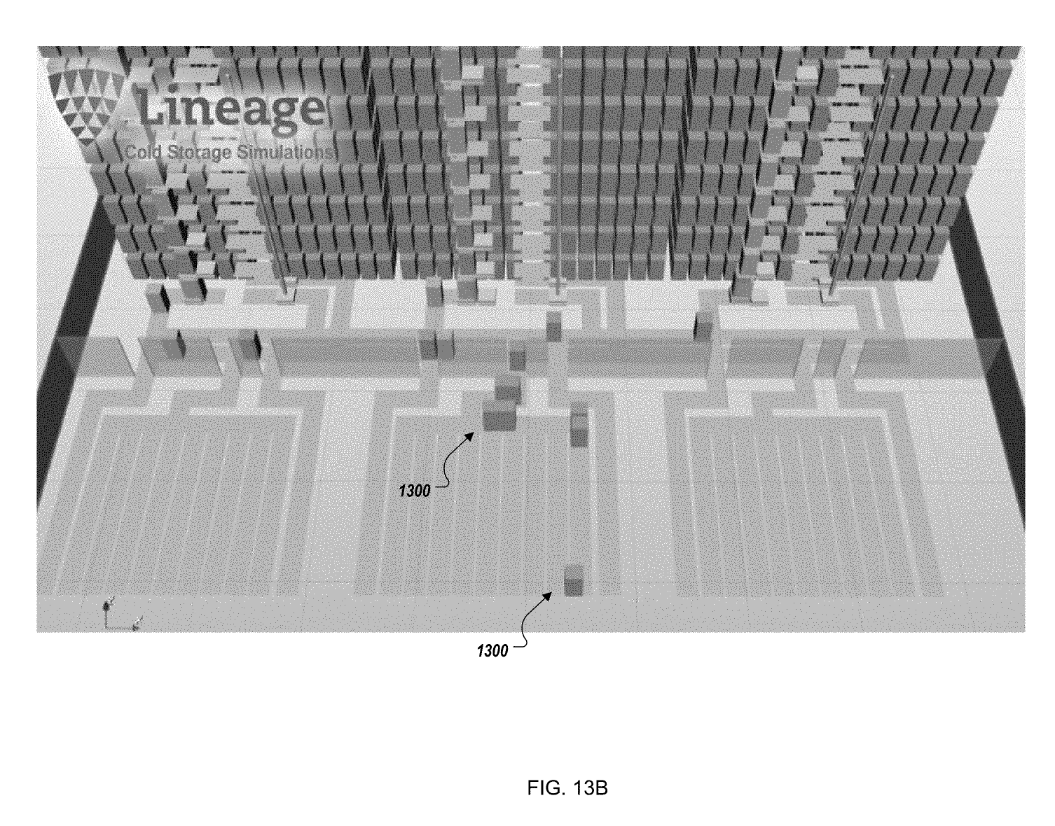

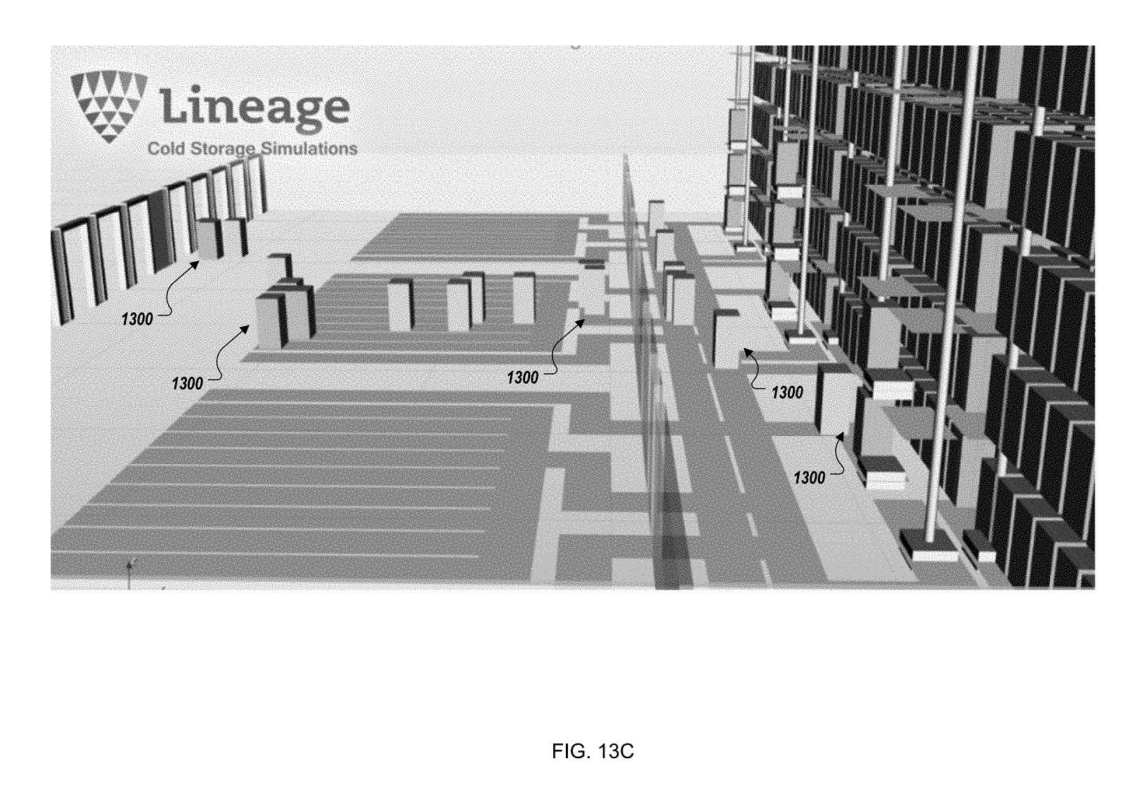

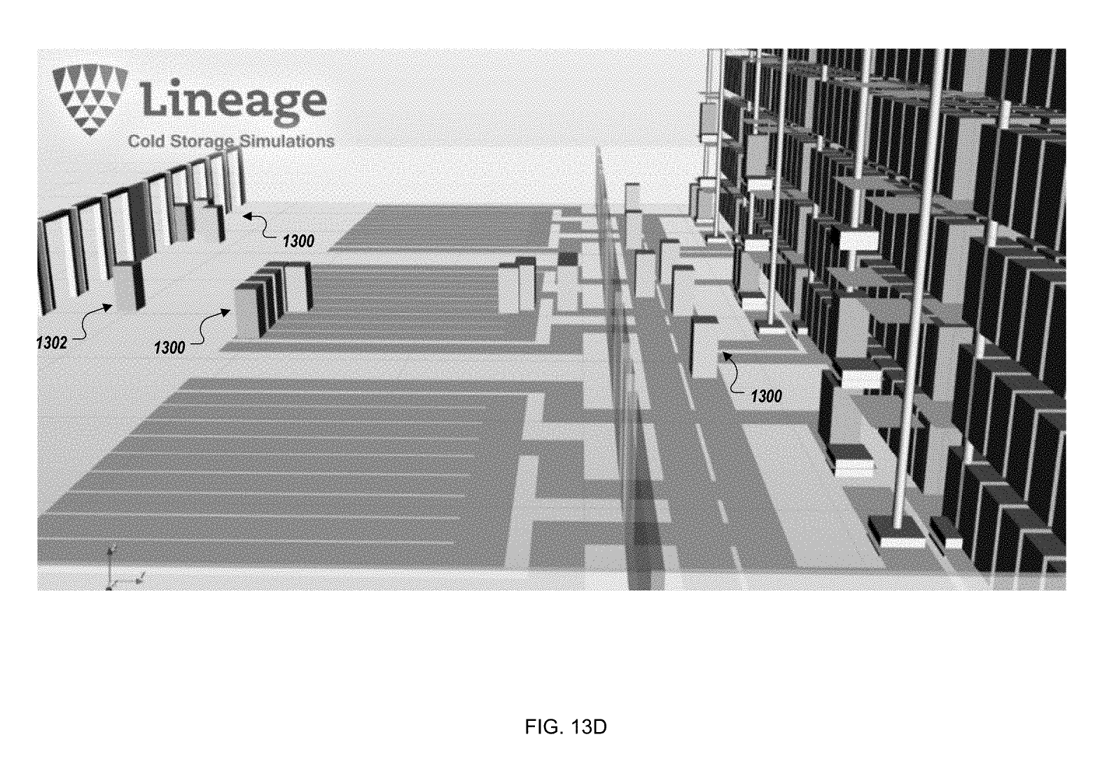

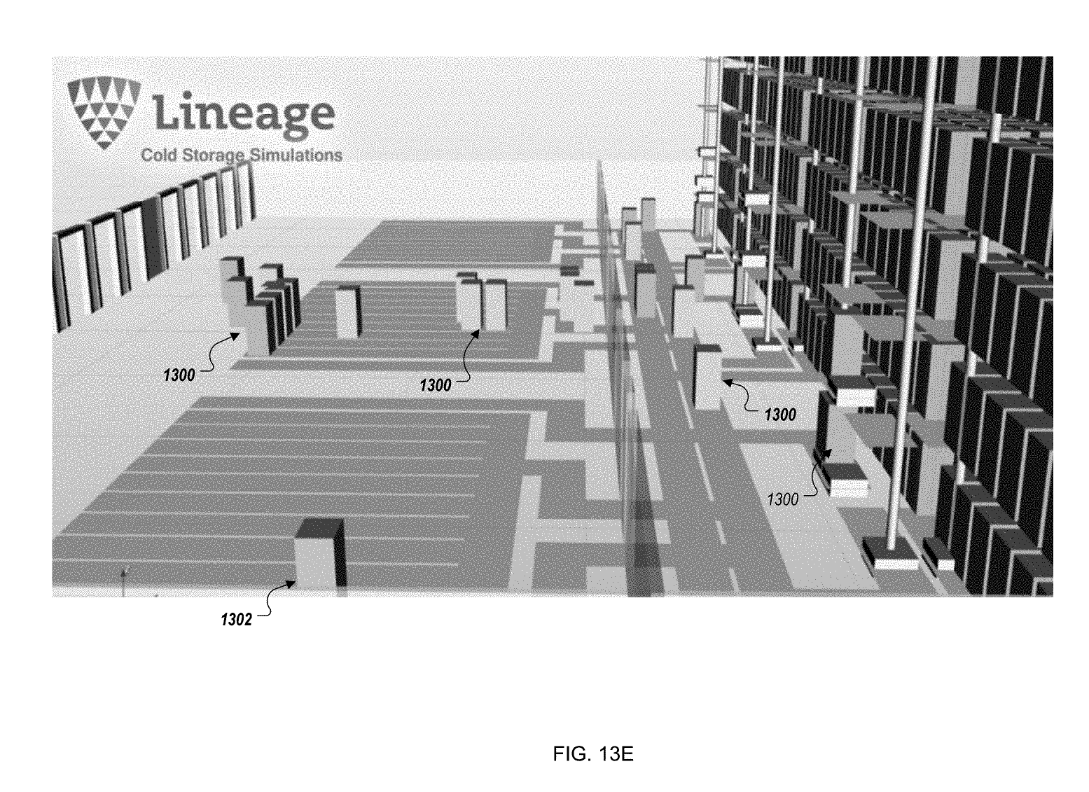

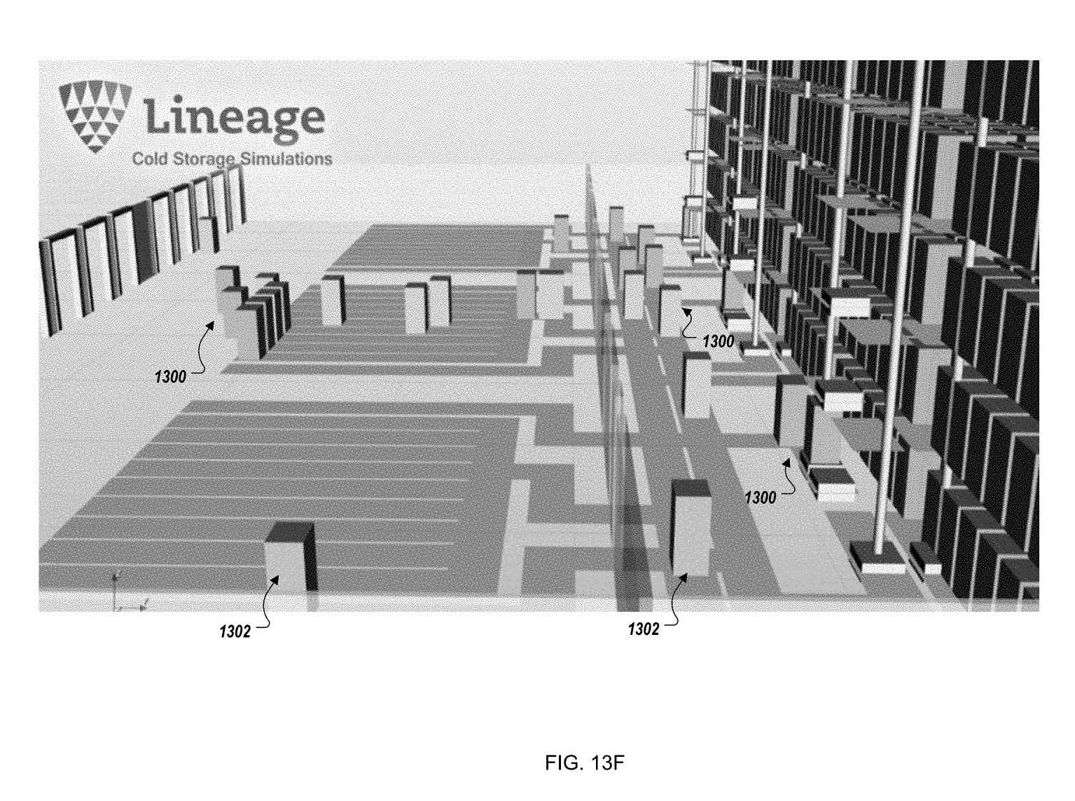

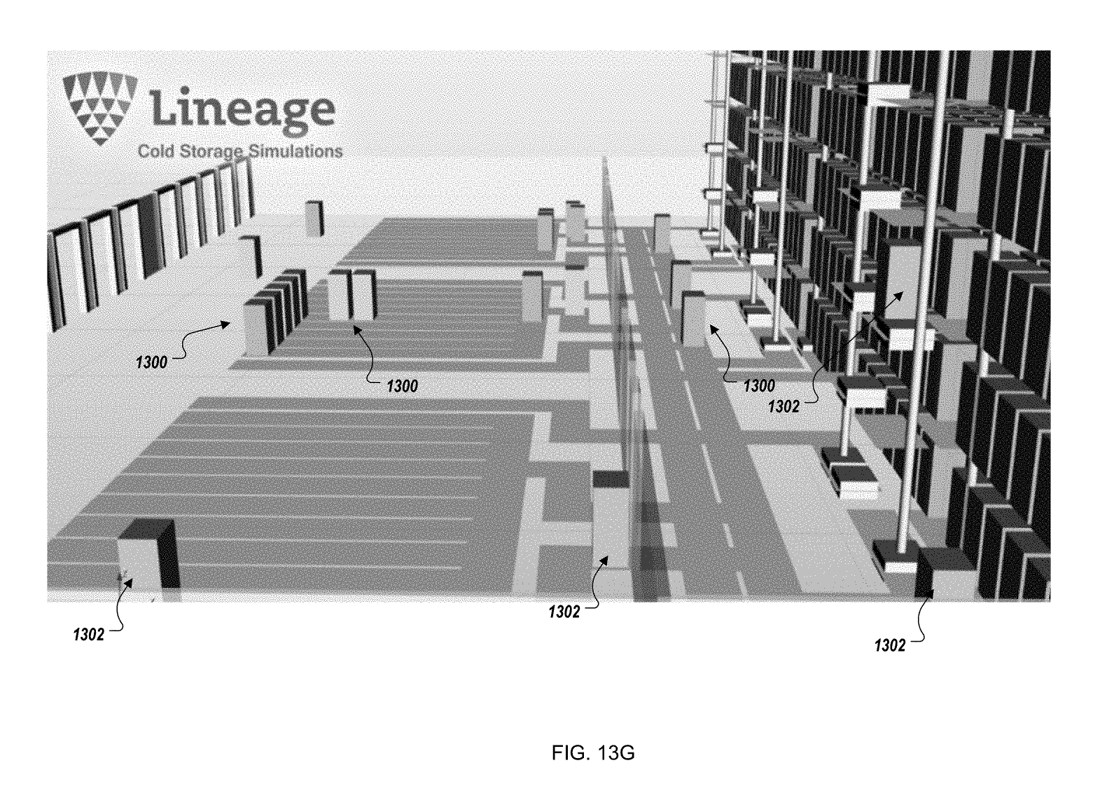

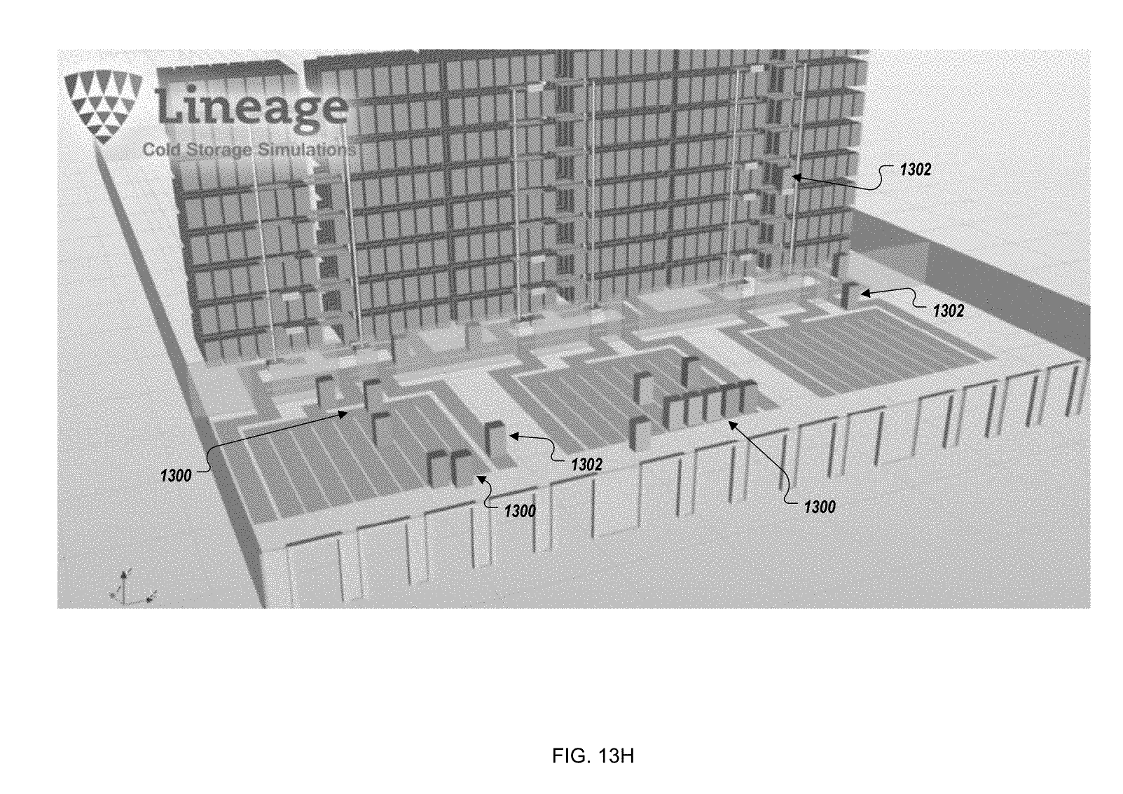

FIGS. 13A-H are 3D renderings of automated warehouse simulations. The example simulations can be performed using the techniques and systems described throughout this document, such as the techniques 400, 600, 900, 1000, 1050, 1100, and 1150, and the system 500. FIGS. 13A-C depict the simulation of outbound pallets 1300 being picked from storage locations and transported to outbound trucks. FIGS. 13D-H depict the simulation of both outbound pallets 1300 being picked from storage locations and transported to outbound trucks, and inbound pallets 1302 being transported from inbound trucks to storage locations in the warehouse.

FIG. 14A is a flowchart of an example technique 1400 for recording simulation data. The example technique 1400 can be performed, for example, as part of the recording step 410 in the technique 400 and as part of the logging steps 912 and 924 in the technique 900, and can be performed by any of a variety of appropriate systems, such as the system 500.

Pallets are detected as arriving at target locations (checkpoints) in the simulated warehouse automation (1402). For example, pallets are detected as arriving at the checkpoints described above with regard to FIGS. 2A and 8. Checkpoints can be, for instance, locations where events occur, such as pallets changing direction and/or otherwise have their movement within the warehouse modified. For instance, checkpoints can be instances where pallets are picked up by forklifts, placed on/removed from a conveyor by a forklift, moving between different conveyors, traveling through a doors between different areas in a warehouse (e.g., travelling through a door into or out of a frozen storage area of a warehouse), transitioning between conveyors to cranes, transitioning between cranes and shuttle systems/carts, and being placed at/removed from storage locations in racks in the warehouse.

Timestamps for the simulated time at which the arrival at the target location (checkpoints) occurs are determined (1404). For example, a timestamp within the simulation can be identified when an event for a pallet occurs, such as the pallet arriving at a checkpoint (e.g., turn, transition within the simulation).

The arrival event is logged using the timestamps, a pallet identifier, and an identifier for the location where the arrival action was detected (1406). The location identifier can be recorded, for example, using a coordinate-based system that identifies the coordinate within a simulated warehouse where an event occurred. For example, a simulated warehouse and simulated objects within it (e.g., automated components, pallets, trucks, forklifts) can be simulated as having coordinates that may or may not change over time, depending on the type of component (e.g., coordinates for a conveyor will not change within the simulation, coordinates for pallets and forklifts will change within simulation). The location of the pallets (and other objects) when various events occur (e.g., arriving at checkpoint) can be identified as a coordinate of the pallets when the event occurred. The logged data can be used to determine and analyze the performance of the simulation on the automated warehouse design that is under test.

FIG. 14B depicts an example log of simulation data for an automated warehouse simulation.

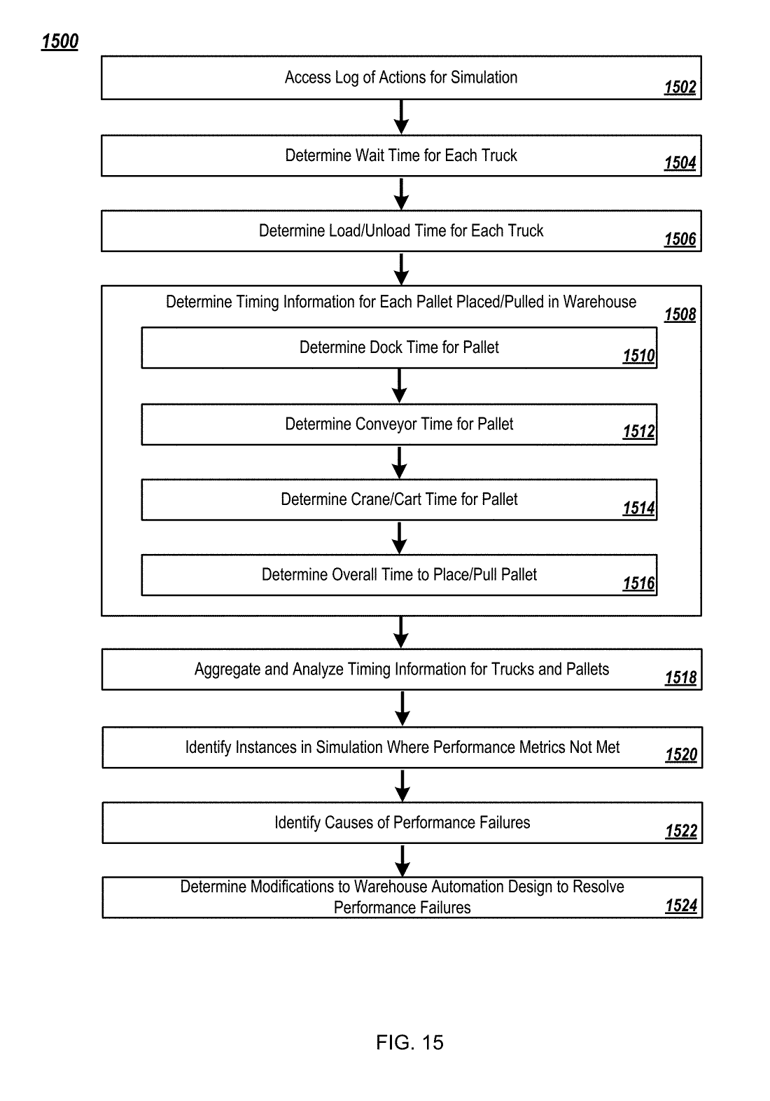

FIG. 15 is a flowchart of an example technique 1500 for analyzing the simulation data and determining simulation results. The example technique 1500 can be performed, for example, as part of the analyzing and evaluating steps 412 and 414 in the technique 400, and can be performed by any of a variety of appropriate systems, such as the system 500.

The log of actions for the simulation can be accessed (1502) and can be used to determine a variety of duration information indicating how long the automated warehouse being simulated took to perform various tasks on the historical inventory data being used for the simulation. For example, the log actions can be used to determine: the wait time for each inbound and outbound truck (1504), the load/unload time for each truck (1506), and the timing information for each pallet being placed/pulled in the warehouse (1508), which can include the dock time for each pallet (1510), the conveyor time for each pallet (1512), the crane and/or cart time for each pallet (1514), and the overall pull/place time for each pallet (1516).

The timing/duration information can be aggregated and analyzed for both trucks and pallets (1518). For example, the timing/duration information can be combined to determine statistics for the simulation, such as mean, median, mode, standard deviation, max, minimum, and/or other statistical measures of the simulation's performance. In another example, the timing/duration information can be plotted over time and/or videos/images can be generated of the simulation so that the performance can be readily visualized.

In some implementations, the step 1508 can additionally and/or alternatively involve aggregating the simulation logs and querying them on a per warehouse coordinate basis over a period of time. The number of results from each query can indicate the number of pallets that passed through that location within the queried time period. By performing the queries for each of the coordinates within the warehouse over one or more periods of simulated time (e.g., over the entire simulation, over one year, one month, one week), the number of pallets (e.g., aggregate, average, median, standard deviation) passing through each location in the warehouse over one or more periods of time can be determined and used to compare the use of different parts of the simulated warehouse. For example, locations that handle a heavier volume of pallets will have a larger number of pallets for a given time period and locations that handle a smaller volume of pallets will have a smaller number of pallets for a given time period. To achieve optimal efficiency, it can be an objective to have balance across each type of component (e.g., conveyor, crane, shuttle, forklift) within the warehouse handle a similar number of pallets so that the pallet load is evenly distributed across the warehouse. Areas of the warehouse with higher volumes can be considered bottlenecks that will potentially constrain the flow of pallets in and out of the warehouse, and that will ultimately have a higher likelihood of reducing the efficiency of the automated warehouse system.

The analysis can be used to compare the simulation performance against one or more performance metrics which, if not met, can indicate that the automated warehouse design is not sufficient for the inventory that is being stress tested on the design. Instances in which the simulation did not meet such performance metrics can be identified (1520), such as inventory requirements that caused a pick or put operation to exceed a maximum allowable time, an average number of pallets (over a time period) travelling through a location in the simulated warehouse exceeding a threshold value, an average number of pallets for a particular type of automated component exceeding the average number of pallets for other components of the particular type by a threshold amount (e.g., exceeding by 20%, 50%, 75%, 100%), and/or other absolute and/or relative comparison metrics. The causes of the performance metrics not being met can be identified (1522). For example, bottlenecks within the simulated warehouse can be identified by evaluating the duration for pallets to travel along components and/or by identifying a volume of pallets (e.g., average number of pallets per minute) to travel along components. For instance, components that have duration and/or volume in excess of an absolute value (e.g., exceeding a threshold value) and/or relative value (e.g., exceeding duration and/or volume for other redundant components in the warehouse by a threshold amount, such as a threshold percentage deviation) can be identified as bottlenecks that are in need of modification to either the component and/or other components within the warehouse to alleviate the bottlenecks. Modifications to the automation design can be determined that would remedy the performance problem (1524). For example, to identify suitable modifications, variations in the automated design can be generated (e.g., add conveyor, reconfigure conveyors) and a mini-simulation can be run on a window of time around instances when the performance metric was not met to determine whether the modification will remedy the problem. Such mini-simulations can be performed iteratively and repeatedly on modifications until a suitable modification is identified.

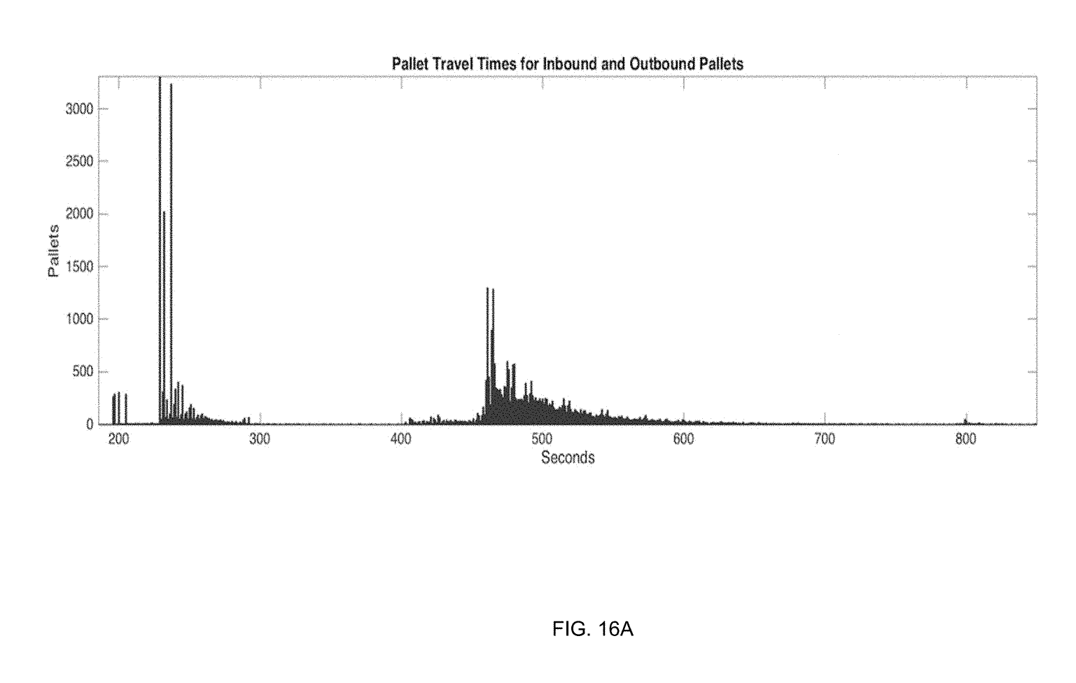

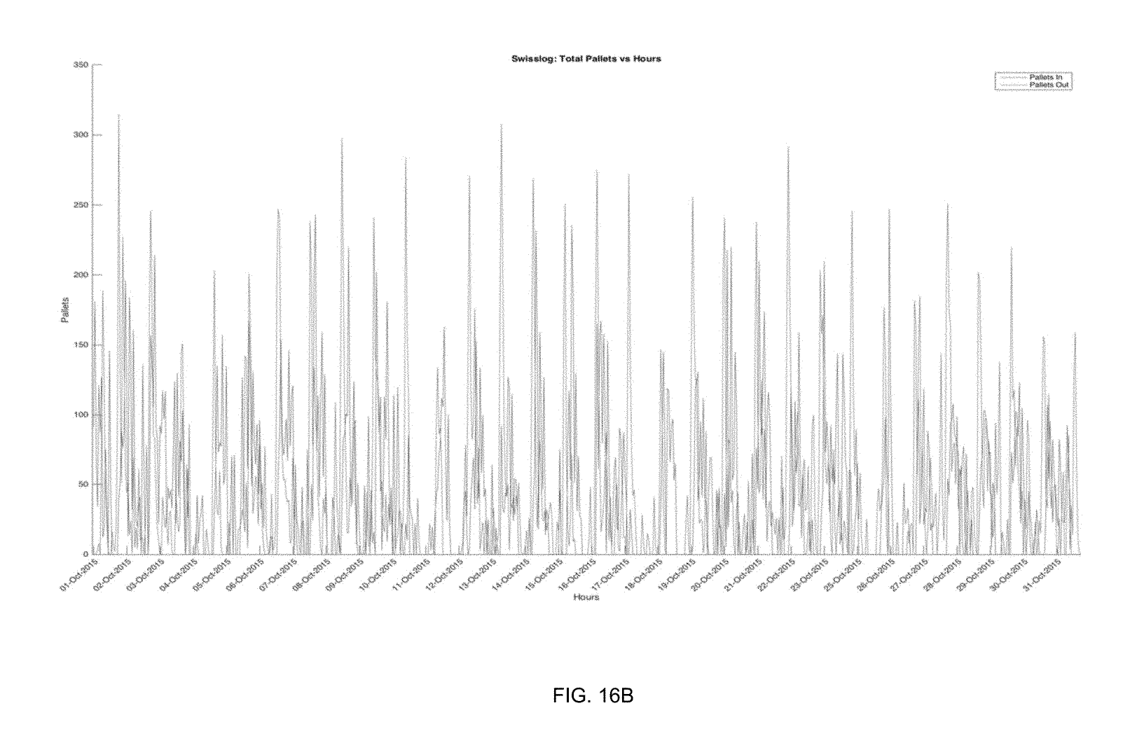

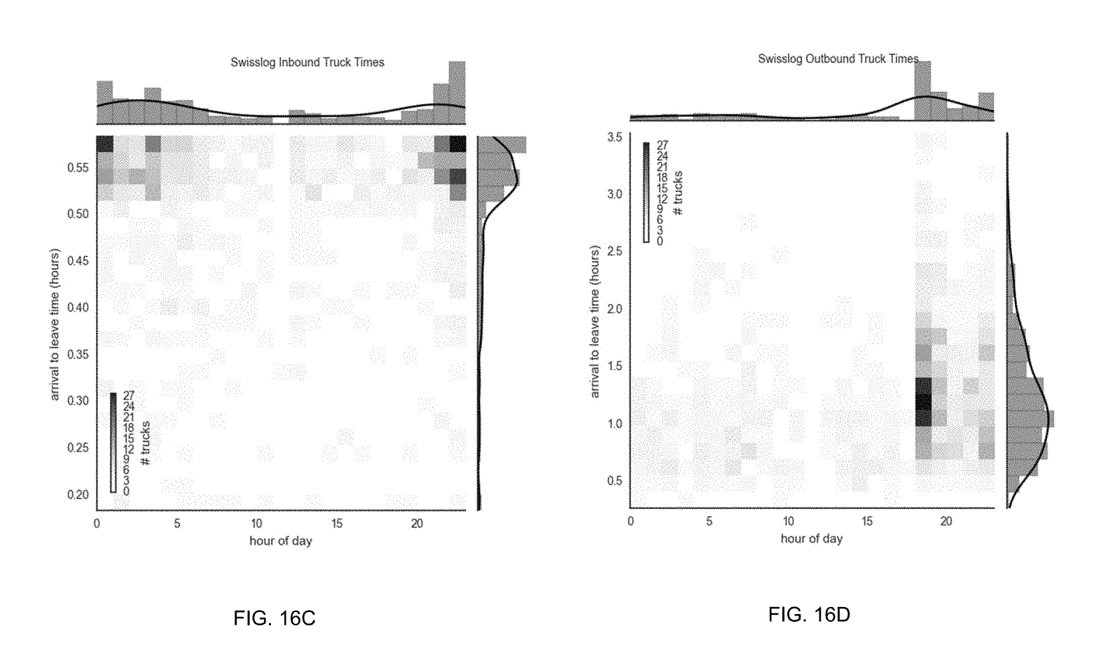

FIGS. 16A-D are charts depicting example automated warehouse simulation results. The charts can be generated, for example, based on the performance of the technique 1500. FIG. 16A is a chart of an example frequency distribution of the amount of time it took inbound and outbound pallets to travel between storage locations and trucks as part of a simulation. FIG. 16B is a chart depicting the inbound and outbound pallets over time when pallets are coming or going out of the dock doors. FIGS. 16C-D are chart detailing the correlation between the times when trucks arrive and depart from a facility, along with the volume of trucks at those times.

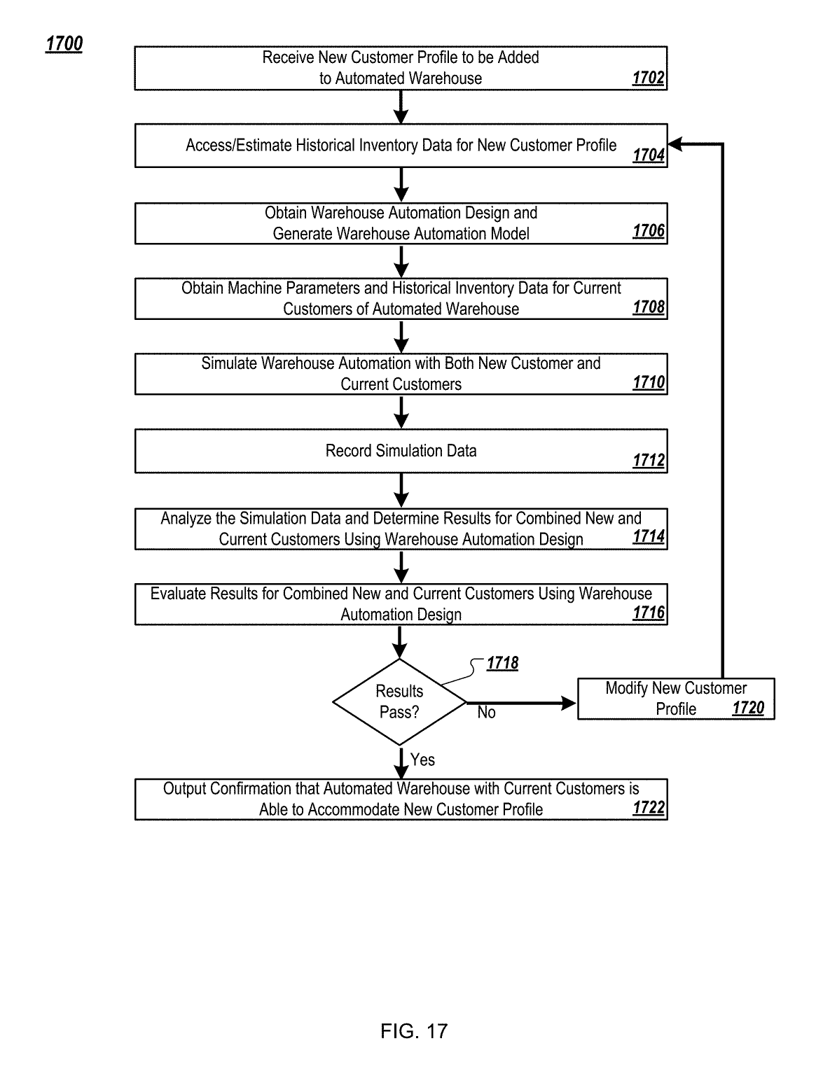

FIG. 17 is a flowchart of an example technique 1700 for simulating the impact of an inventory modification for an automated warehouse on the warehouse's performance. The example technique 1700 can be performed by any of a variety of appropriate systems, such as the system 500. The technique 1700 can be used to readily assess whether a modification to the inventory profile for a warehouse, such as by adding a new customer inventory profile to the warehouse, is permissible and will continue to permit the warehouse to meet performance metrics. The technique 1700 can be similar to the technique 400, but with the addition of a new customer profile to an existing inventory profile for existing customers, and with a preexisting warehouse design for an existing warehouse instead of an automated warehouse design that is still subject to revisions and modifications.

A new customer profile to be added to the automated warehouse is received (1702). If available, historic inventory data for the new customer profile can be accessed, otherwise inventory data for the new customer profile can be estimated based on the customer's expected usage of the warehouse over time (1704). Similar to steps 402 and 404, the warehouse automation design can be obtained and used to generate a warehouse automation model to be used for the simulation (1706). Similar to step 406, machine parameters and historical inventory data for current customers of the automated warehouse can be obtained (1708). Similar to step 408, warehouse operations and automation can be simulated for the combination of the new customer and existing customers at the warehouse (1710), and, similar to step 410, simulation data can be recorded (1712). Similar to step 412, simulation data can be analyzed and results can be determined for the combination of the new and current customers using the warehouse automation design (1714), and, similar to step 414, those results can be evaluated (1716). Similar to step 416, those results can be assessed to determine whether they pass one or more performance metrics (1718). If they do not, then the new customer profile can be modified and retested with a new simulation to determine whether a modified new customer profile will be suitable with the existing customers and the automation design (1720). If they do pass, then confirmation that the automated warehouse will be able to accommodate the new customer with the existing customers can be output.

Although the above description pertains to simulating and optimizing automated warehouse design, these technologies can additionally be applied to manual warehouses. For example, manual warehouses—meaning warehouses that rely on human operators (e.g., forklift operators) to control equipment (e.g., forklifts, cranes) placing and pulling pallets within the warehouse—can be simulated in a similar manner to automated warehouses, with attributes being applied to human operators in a similar manner to their attribution to automated machines. An additional hurdle in effectively modeling manual warehouses is accounting for variability in human operators and variability in their performance over time. Such variability can additionally be modeled through human operator parameters, which can account for variation in reaction time, speed, skill level, and other parameters. Human operator parameters can be modeled from, for example, analysis historical performance data on puts, pulls, and other actions performed within a warehouse. Warehouse designs and layouts for manual warehouses can similarly be modeled and stress tested through simulations, as described above. For example, the layout of racks, the spacing of aisles between racks, the dock configuration, and the truck door/bay configuration can be modeled through different designs. Simulations of human operators in such designs can be run, simulation data can be recorded and analyzed, and improvements/optimizations to the manual warehouse designs under test can be determined and iteratively tested.

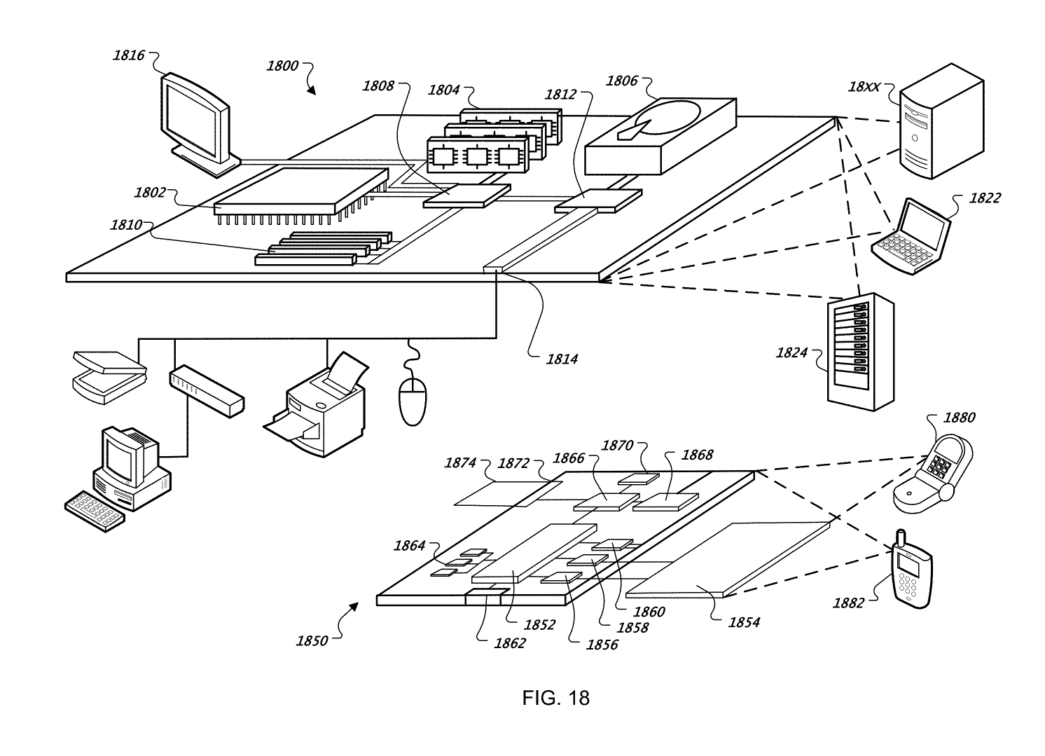

FIG. 18 is a block diagram of computing devices 1800, 1850 that may be used to implement the systems and methods described in this document, as either a client or as a server or plurality of servers. Computing device 1800 is intended to represent various forms of digital computers, such as laptops, desktops, workstations, personal digital assistants, servers, blade servers, mainframes, and other appropriate computers. Computing device 1850 is intended to represent various forms of mobile devices, such as personal digital assistants, cellular telephones, smartphones, and other similar computing devices. Additionally computing device 1800 or 1850 can include Universal Serial Bus (USB) flash drives. The USB flash drives may store operating systems and other applications. The USB flash drives can include input/output components, such as a wireless transmitter or USB connector that may be inserted into a USB port of another computing device. The components shown here, their connections and relationships, and their functions, are meant to be exemplary only, and are not meant to limit implementations described and/or claimed in this document.

Computing device 1800 includes a processor 1802, memory 1804, a storage device 1806, a high-speed interface 1808 connecting to memory 1804 and high-speed expansion ports 1810, and a low speed interface 1812 connecting to low speed bus 1814 and storage device 1806. Each of the components 1802, 1804, 1806, 1808, 1810, and 1812, are interconnected using various busses, and may be mounted on a common motherboard or in other manners as appropriate. The processor 1802 can process instructions for execution within the computing device 1800, including instructions stored in the memory 1804 or on the storage device 1806 to display graphical information for a GUI on an external input/output device, such as display 1816 coupled to high speed interface 1808. In other implementations, multiple processors and/or multiple buses may be used, as appropriate, along with multiple memories and types of memory. Also, multiple computing devices 1800 may be connected, with each device providing portions of the necessary operations (e.g., as a server bank, a group of blade servers, or a multi-processor system).

The memory 1804 stores information within the computing device 1800. In one implementation, the memory 1804 is a volatile memory unit or units. In another implementation, the memory 1804 is a non-volatile memory unit or units. The memory 1804 may also be another form of computer-readable medium, such as a magnetic or optical disk.

The storage device 1806 is capable of providing mass storage for the computing device 1800. In one implementation, the storage device 1806 may be or contain a computer-readable medium, such as a floppy disk device, a hard disk device, an optical disk device, or a tape device, a flash memory or other similar solid state memory device, or an array of devices, including devices in a storage area network or other configurations. A computer program product can be tangibly embodied in an information carrier. The computer program product may also contain instructions that, when executed, perform one or more methods, such as those described above. The information carrier is a computer- or machine-readable medium, such as the memory 1804, the storage device 1806, or memory on processor 1802.

The high speed controller 1808 manages bandwidth-intensive operations for the computing device 1800, while the low speed controller 1812 manages lower bandwidth-intensive operations. Such allocation of functions is exemplary only. In one implementation, the high-speed controller 1808 is coupled to memory 1804, display 1816 (e.g., through a graphics processor or accelerator), and to high-speed expansion ports 1810, which may accept various expansion cards (not shown). In the implementation, low-speed controller 1812 is coupled to storage device 1806 and low-speed expansion port 1814. The low-speed expansion port, which may include various communication ports (e.g., USB, Bluetooth, Ethernet, wireless Ethernet) may be coupled to one or more input/output devices, such as a keyboard, a pointing device, a scanner, or a networking device such as a switch or router, e.g., through a network adapter.

The computing device 1800 may be implemented in a number of different forms, as shown in the figure. For example, it may be implemented as a standard server 1820, or multiple times in a group of such servers. It may also be implemented as part of a rack server system 1824. In addition, it may be implemented in a personal computer such as a laptop computer 1822. Alternatively, components from computing device 1800 may be combined with other components in a mobile device (not shown), such as device 1850. Each of such devices may contain one or more of computing device 1800, 1850, and an entire system may be made up of multiple computing devices 1800, 1850 communicating with each other.

Computing device 1850 includes a processor 1852, memory 1864, an input/output device such as a display 1854, a communication interface 1866, and a transceiver 1868, among other components. The device 1850 may also be provided with a storage device, such as a microdrive or other device, to provide additional storage. Each of the components 1850, 1852, 1864, 1854, 1866, and 1868, are interconnected using various buses, and several of the components may be mounted on a common motherboard or in other manners as appropriate.

The processor 1852 can execute instructions within the computing device 1850, including instructions stored in the memory 1864. The processor may be implemented as a chipset of chips that include separate and multiple analog and digital processors. Additionally, the processor may be implemented using any of a number of architectures. For example, the processor 410 may be a CISC (Complex Instruction Set Computers) processor, a RISC (Reduced Instruction Set Computer) processor, or a MISC (Minimal Instruction Set Computer) processor. The processor may provide, for example, for coordination of the other components of the device 1850, such as control of user interfaces, applications run by device 1850, and wireless communication by device 1850.

Processor 1852 may communicate with a user through control interface 1858 and display interface 1856 coupled to a display 1854. The display 1854 may be, for example, a TFT (Thin-Film-Transistor Liquid Crystal Display) display or an OLED (Organic Light Emitting Diode) display, or other appropriate display technology. The display interface 1856 may comprise appropriate circuitry for driving the display 1854 to present graphical and other information to a user. The control interface 1858 may receive commands from a user and convert them for submission to the processor 1852. In addition, an external interface 1862 may be provide in communication with processor 1852, so as to enable near area communication of device 1850 with other devices. External interface 1862 may provide, for example, for wired communication in some implementations, or for wireless communication in other implementations, and multiple interfaces may also be used.

The memory 1864 stores information within the computing device 1850. The memory 1864 can be implemented as one or more of a computer-readable medium or media, a volatile memory unit or units, or a non-volatile memory unit or units. Expansion memory 1874 may also be provided and connected to device 1850 through expansion interface 1872, which may include, for example, a SIMM (Single In Line Memory Module) card interface. Such expansion memory 1874 may provide extra storage space for device 1850, or may also store applications or other information for device 1850. Specifically, expansion memory 1874 may include instructions to carry out or supplement the processes described above, and may include secure information also. Thus, for example, expansion memory 1874 may be provide as a security module for device 1850, and may be programmed with instructions that permit secure use of device 1850. In addition, secure applications may be provided via the SIMM cards, along with additional information, such as placing identifying information on the SIMM card in a non-hackable manner.

The memory may include, for example, flash memory and/or NVRAM memory, as discussed below. In one implementation, a computer program product is tangibly embodied in an information carrier. The computer program product contains instructions that, when executed, perform one or more methods, such as those described above. The information carrier is a computer- or machine-readable medium, such as the memory 1864, expansion memory 1874, or memory on processor 1852 that may be received, for example, over transceiver 1868 or external interface 1862.

Device 1850 may communicate wirelessly through communication interface 1866, which may include digital signal processing circuitry where necessary. Communication interface 1866 may provide for communications under various modes or protocols, such as GSM voice calls, SMS, EMS, or MMS messaging, CDMA, TDMA, PDC, WCDMA, CDMA2000, or GPRS, among others. Such communication may occur, for example, through radio-frequency transceiver 1868. In addition, short-range communication may occur, such as using a Bluetooth, WiFi, or other such transceiver (not shown). In addition, GPS (Global Positioning System) receiver module 1870 may provide additional navigation- and location-related wireless data to device 1850, which may be used as appropriate by applications running on device 1850.

Device 1850 may also communicate audibly using audio codec 1860, which may receive spoken information from a user and convert it to usable digital information. Audio codec 1860 may likewise generate audible sound for a user, such as through a speaker, e.g., in a handset of device 1850. Such sound may include sound from voice telephone calls, may include recorded sound (e.g., voice messages, music files, etc.) and may also include sound generated by applications operating on device 1850.

The computing device 1850 may be implemented in a number of different forms, as shown in the figure. For example, it may be implemented as a cellular telephone 1880. It may also be implemented as part of a smartphone 1882, personal digital assistant, or other similar mobile device.

Various implementations of the systems and techniques described here can be realized in digital electronic circuitry, integrated circuitry, specially designed ASICs (application specific integrated circuits), computer hardware, firmware, software, and/or combinations thereof. These various implementations can include implementation in one or more computer programs that are executable and/or interpretable on a programmable system including at least one programmable processor, which may be special or general purpose, coupled to receive data and instructions from, and to transmit data and instructions to, a storage system, at least one input device, and at least one output device.

These computer programs (also known as programs, software, software applications or code) include machine instructions for a programmable processor, and can be implemented in a high-level procedural and/or object-oriented programming language, and/or in assembly/machine language. As used herein, the terms “machine-readable medium” “computer-readable medium” refers to any computer program product, apparatus and/or device (e.g., magnetic discs, optical disks, memory, Programmable Logic Devices (PLDs)) used to provide machine instructions and/or data to a programmable processor, including a machine-readable medium that receives machine instructions as a machine-readable signal. The term “machine-readable signal” refers to any signal used to provide machine instructions and/or data to a programmable processor.

To provide for interaction with a user, the systems and techniques described here can be implemented on a computer having a display device (e.g., a CRT (cathode ray tube) or LCD (liquid crystal display) monitor) for displaying information to the user and a keyboard and a pointing device (e.g., a mouse or a trackball) by which the user can provide input to the computer. Other kinds of devices can be used to provide for interaction with a user as well; for example, feedback provided to the user can be any form of sensory feedback (e.g., visual feedback, auditory feedback, or tactile feedback); and input from the user can be received in any form, including acoustic, speech, or tactile input.

The systems and techniques described here can be implemented in a computing system that includes a back end component (e.g., as a data server), or that includes a middleware component (e.g., an application server), or that includes a front end component (e.g., a client computer having a graphical user interface or a Web browser through which a user can interact with an implementation of the systems and techniques described here), or any combination of such back end, middleware, or front end components. The components of the system can be interconnected by any form or medium of digital data communication (e.g., a communication network). Examples of communication networks include a local area network (“LAN”), a wide area network (“WAN”), peer-to-peer networks (having ad-hoc or static members), grid computing infrastructures, and the Internet.

The computing system can include clients and servers. A client and server are generally remote from each other and typically interact through a communication network. The relationship of client and server arises by virtue of computer programs running on the respective computers and having a client-server relationship to each other.

Although a few implementations have been described in detail above, other modifications are possible. Moreover, other mechanisms for performing the systems and methods described in this document may be used. In addition, the logic flows depicted in the figures do not require the particular order shown, or sequential order, to achieve desirable results. Other steps may be provided, or steps may be eliminated, from the described flows, and other components may be added to, or removed from, the described systems. Accordingly, other implementations are within the scope of the following claims.

What is claimed is:

1. A system for optimizing warehouse automation design, the system comprising:
an automated warehouse design database that is programmed to store a warehouse automation model for a current automation design for a warehouse, the current automation design including automation components to automate storage of pallets within the warehouse;
a historical inventory database that is programmed to store historical inventory data for the warehouse, the historical inventory data identifying, at least, pallets stored in the warehouse, times at which the pallets were stored and removed from the warehouse, and truck identifiers for trucks carrying the pallets; and
an automated warehouse design simulator including one or more processors that are configured to:
access the historical inventory information and the warehouse automation model;
chronologically simulate, according to the specific timing included in the historical inventory data, storage and retrieval of the pallets on the current automation design for the warehouse using the warehouse automation model, wherein the warehouse automation model (i) maps functional and physical relationships between the automation components, and (ii) includes movement parameters for the automation components;
detect arrival of the pallets at checkpoints within the current automation design for a warehouse;
record timestamps for simulated times at which the pallets arrived at the checkpoints;
assess performance of the current automation design for a warehouse under the simulation based on analysis of the recorded timestamps; and
output the performance information for the current automation design for a warehouse.

2. The system of claim 1, wherein the automation components include conveyor belts to transport pallets from a dock to racks in the warehouse, cranes to carry pallets to different rack levels, and carts to transport pallets across rack openings on a same rack level.

3. The system of claim 2, wherein, for each of the automation components, the movement parameters include a rate of acceleration, a maximum velocity, a receiving delay, a process delay, and an eject delay.

4. The system of claim 2, wherein the checkpoints include doors entering the warehouse, transition points between the dock and the conveyor belts, transition points between the conveyor belts and the cranes, transition points between the cranes and the carts, and placement of pallets in target rack openings in the warehouse.

5. The system of claim 1, wherein the performance assessment comprises determining whether the current automation design for a warehouse failed to meet one or more performance metrics under the simulation.

6. The system of claim 5, wherein the performance metrics comprise a maximum amount of time to transport pallets between trucks and storage locations.

7. The system of claim 5, wherein the performance metrics comprise a maximum amount of time for trucks to wait to dock at the warehouse.

8. The system of claim 5, wherein the performance metrics comprise a maximum amount of time for trucks to be loaded or unloaded with pallets.

9. The system of claim 5, wherein, in response to determining that the current automation design failed, performing additional operations comprising:
modifying one or more of the automation components in the current automation design to generate a revised automation design for the warehouse;
generating a revised warehouse automation model for the revised automation design;
repeating the chronological simulation, detecting, recording, and assessing with the revised warehouse automation model and the same historical inventory data;
determining whether the revised automation design for the warehouse is an improvement over the previous automation design for the warehouse based on comparison of the performance assessments; and
outputting information identifying an optimal automation design for the warehouse based on the determination.

10. The system of claim 9, further comprising the warehouse, wherein the warehouse is reconfigured from the current automation design according to the revised automation design.

11. The system of claim 1, further comprising:
a warehouse management system that is configured to perform the following operations to direct the automation components on the placement of a pallets in the storage racks.

12. The system of claim 1, further comprising the warehouse, including the automation components to automate storage of pallets within the warehouse.

13. A method for optimizing warehouse automation design, comprising:
accessing, by an automated warehouse design simulator:
(i) historical inventory data for a warehouse that identifies, at least, pallets stored in the warehouse, times at which the pallets were stored and removed from the warehouse, and truck identifiers for trucks carrying the pallets, and
(ii) a warehouse automation model for a current automation design for the warehouse, the current automation design including automation components to automate storage of the pallets within the warehouse, the warehouse automation model (a) mapping functional and physical relationships among the automation components, and (b) storing movement parameters for the automation components;
chronologically simulating, by the automated warehouse design simulator and according to the specific timing included in the historical inventory data, storage and retrieval of the pallets on the current automation design for the warehouse using the warehouse automation model;
detecting, by the automated warehouse design simulator, arrival of the pallets at checkpoints within the current automation design for a warehouse;
recording timestamps for simulated times at which the pallets arrived at the checkpoints;
assessing, by the automated warehouse design simulator, performance of the current automation design for a warehouse under the simulation based on analysis of the recorded timestamps; and
outputting the performance information for the current automation design for the warehouse.

14. The method of claim 13, wherein the automation components include conveyor belts to transport pallets from a dock to racks in the warehouse, cranes to carry pallets to different rack levels, and carts to transport pallets across rack openings on a same rack level.

15. The method of claim 14, wherein, for each of the automation components, the movement parameters include a rate of acceleration, a maximum velocity, a receiving delay, a process delay, and an eject delay.

16. The method of claim 14, wherein the checkpoints include doors entering the warehouse, transition points between the dock and the conveyor belts, transition points between the conveyor belts and the cranes, transition points between the cranes and the carts, and placement of pallets in target rack openings in the warehouse.

17. The method of claim 13, wherein the performance assessment comprises determining whether the current automation design for a warehouse failed to meet one or more performance metrics under the simulation.

18. The method of claim 17, wherein the performance metrics comprise a maximum amount of time to transport pallets between trucks and storage locations.

19. The method of claim 17, wherein the performance metrics comprise a maximum amount of time for trucks to wait to dock at the warehouse.

20. The method of claim 17, wherein the performance metrics comprise a maximum amount of time for trucks to be loaded or unloaded with pallets.

21. The method of claim 17, further comprising, in response to determining that the current automation design failed:
modifying, by the automated warehouse design simulator, one or more of the automation components in the current automation design to generate a revised automation design for the warehouse;
generating, by the automated warehouse design simulator, a revised warehouse automation model for the revised automation design;
repeating the chronological simulation, detecting, recording, and assessing with the revised warehouse automation model and the same historical inventory data;
determining, by the automated warehouse design simulator, whether the revised automation design for the warehouse is an improvement over the previous automation design for the warehouse based on comparison of the performance assessments; and
outputting information identifying an optimal automation design for the warehouse based on the determination.

22. The method of claim 21, further comprising physically reconfiguring the warehouse according to the revised automation design.
